(19) United States
(12) Patent Application Publication
(10) Pub. No.: US 2026/0353668 A1
(43) Pub. Date: Nov. 5, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Harry-HakLay CHUANG, Zhubei City (TW); Jui-Tsung LIEN, Hsinchu City (TW); Kuo-Chyuan TZENG, Chu-Pei City (TW); Ya-Chen KAO, Taoyuan County (TW); Chen-Chin LIU, Hsinchu City (TW); Yu-Chen WANG, Yunlin County (TW); Jer-Yi LIN, Taichung City (TW); Ting-Shiuan KANG, Taichung City (TW)

(21) Appl. No.: 19/197,485

(22) Filed: May 2, 2025

(51) Int. Cl. H10B 61/00; H10N 50/01; H10N 50/10

(52) U.S. Cl. CPC H10B 61/10; H10N 50/01; H10N 50/10

(57) ABSTRACT

Respective vias of a plurality of vias are commonly connected to an overlying metallization layer, and land on respective top electrode layers of different memory devices. The vias and metallization layer that are connected to the memory devices in a memory region of a semiconductor device may have the same structure as or a similar structure to vias and a metallization layer in an adjacent logic region. As a result, the vias and metallization layers in the memory and logic regions may be manufactured using the same etching and deposition processes. Accordingly, processing to manufacture the vias and a metallization structure in the memory region and corresponding vias and a metallization structure in a logic region requires fewer masks and fewer steps than processing to manufacture other arrangements of metallization structures and vias. The simplified device manufacturing may result in fewer design errors, resulting in increased device performance and reliability.

### BACKGROUND

A semiconductor device may include a non-volatile memory, which is able to store data in the absence of power. Non-volatile memory technologies include magneto-resistive random-access memory (MRAM), phase change random access memory (PC-RAM), and resistive random access memory (RRAM), among other examples. These non-volatile memory technologies are compatible with complementary metal-oxide-semiconductor (CMOS) logic fabrication processes, which enables logic and memory circuitry to be integrated onto the same semiconductor device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1C are diagrams of an example semiconductor device including an example semiconductor memory structure described herein.

FIGS. 2A-2E are diagrams of an example implementation of forming a semiconductor device described herein.

FIGS. 3A-3Z are diagrams of an example implementation of forming a portion of a semiconductor device described herein.

FIG. 4 is a flowchart of an example process associated with forming a semiconductor device including a semiconductor memory structure.

FIG. 5 is a flowchart of an example process associated with forming a semiconductor device including a semiconductor memory structure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An MRAM cell may include a memory device having a magnetic tunnel junction (MTJ) structure arranged vertically between a bottom electrode and a top electrode. Multiple memory devices may be connected to a metallization structure through a single via that is connected to a top electrode structure disposed between the single via and the multiple MRAM cells. Processing to manufacture the arrangement including the metallization structure, single via, and top electrode structure may require multiple masks and extensive processing due to advanced node (e.g., 5 nm node) limitations, increased dielectric layer thicknesses, and a complicated topography of the top electrode structure. In addition, differences between the arrangement of the metallization structure, single via, and top electrode structure from metallization and interconnect structures formed in a region on the side of the arrangement further complicates device manufacturing.

In some implementations, respective vias of a plurality of vias are commonly connected to an overlying metallization layer, and land on respective top electrode layers of different memory devices. The vias and metallization layer that are connected to the memory devices in a memory region of a semiconductor device may have the same structure as or a similar structure to vias and a metallization layer in an adjacent logic region. As a result, the vias and metallization layers in the memory and logic regions may be manufactured using the same etching and deposition processes. Accordingly, processing to manufacture the vias and a metallization structure in the memory region and corresponding vias and a metallization structure in a logic region requires fewer masks and fewer steps than processing to manufacture other arrangements of metallization structures and vias. The simplified device manufacturing may result in fewer design errors, resulting in increased device performance and reliability.

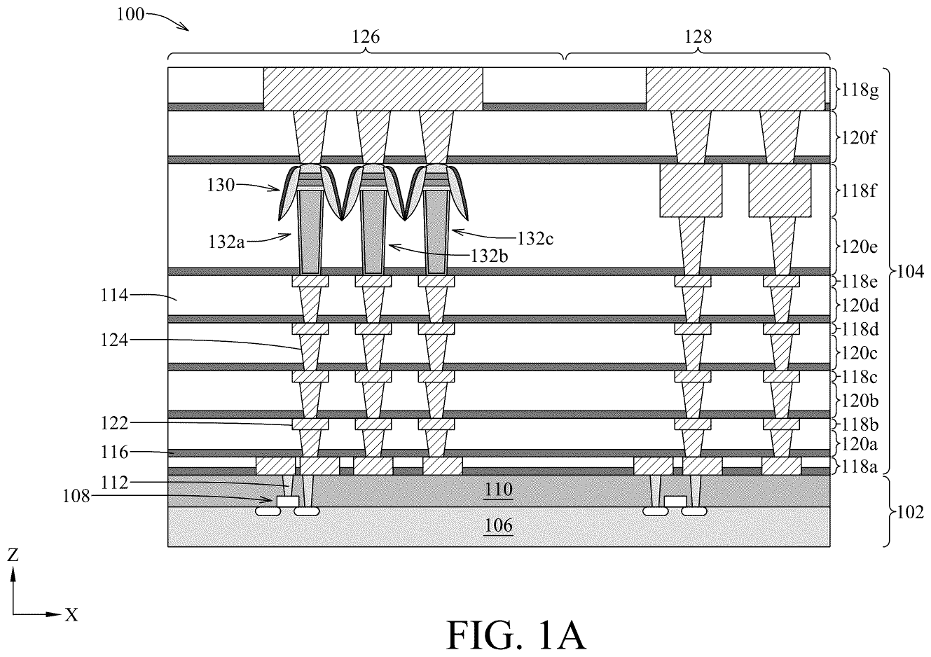

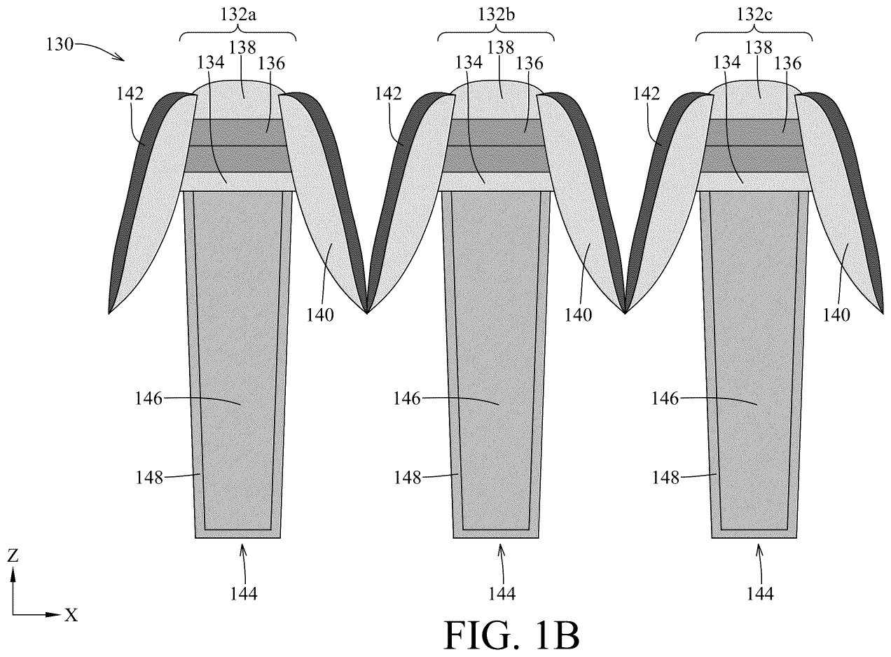

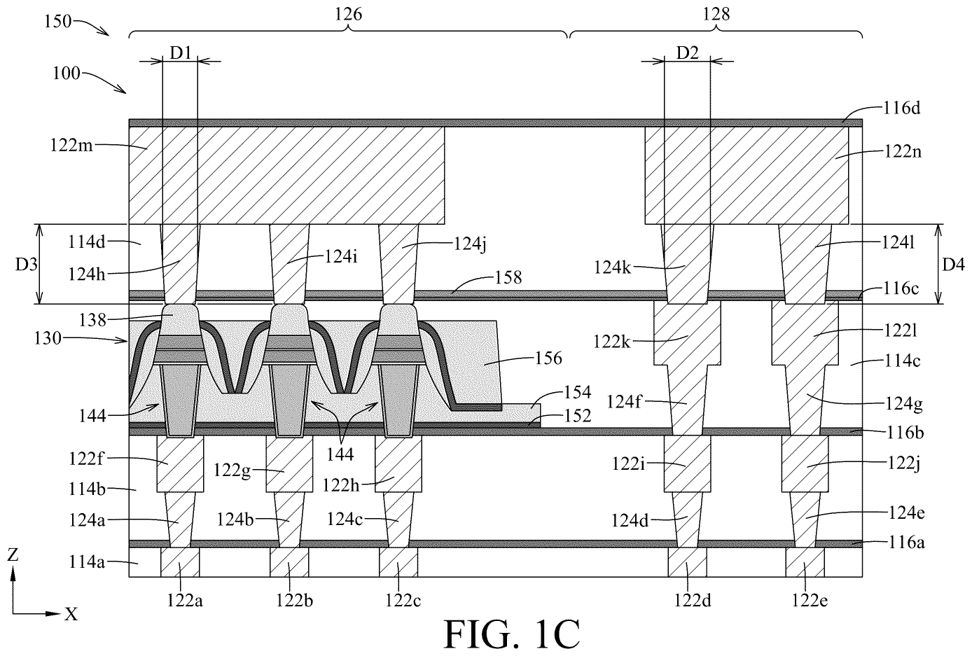

FIGS. 1A-1C are diagrams of an example semiconductor device 100 described herein. The semiconductor device 100 may include a system on chip (SoC) device, a logic device such as a central processing unit (CPU) or a graphics processing unit (GPU), a memory device (e.g., a high bandwidth memory (HBM) device), an image sensor device (e.g., a complementary metal-oxide-semiconductor (CMOS) image sensor device), and/or another type of semiconductor device.

FIG. 1A illustrates a cross-section view of the semiconductor device 100. As shown in FIG. 1A, the semiconductor device 100 may include a device layer 102 and an interconnect layer 104 arranged in a z-direction in the semiconductor device 100 with respect to the device layer 102. For example, the interconnect layer 104 may be located above the device layer 102. As another example, the interconnect layer 104 may be located below the device layer 102.

The interconnect layer 104 may include conductive structures that are arranged to carry signals and/or provide power distribution throughout the semiconductor device 100. In some implementations, the semiconductor device 100 includes interconnect layers 104 above and below the device layer 102. A first interconnect layer 104 on a first side of the device layer 102 may be used for signal propagation throughout the semiconductor device 100, and a second interconnect layer 104 on an opposing second side of the device layer 102 may be used for power distribution in the semiconductor device 100.

The device layer 102 includes a substrate 106 of the semiconductor device 100. The substrate 106 may correspond to a portion of a semiconductor wafer on which the semiconductor device 100 is formed. The substrate 106 may include a silicon (Si) substrate, a substrate formed of a material including silicon, a III-V compound semiconductor material substrate such as gallium arsenide (GaAs), a silicon on insulator (SOI) substrate, or another type of substrate. The substrate 106 may extend in an x-direction and/or in a y-direction in the semiconductor device 100 such that the top and bottom surfaces of the substrate 106 are approximately orthogonal to the z-direction in the semiconductor device 100.

Integrated circuit devices 108 may be included in and/or on the substrate 106 in the device layer 102 of the semiconductor device 100. The integrated circuit devices 108 may include front end transistor structures (e.g., front end planar transistor structures, front end fin field effect transistor (finFET) structures, front end gate all around (GAA) transistor structures), pixel sensors, capacitors, resistors, inductors, photodetectors, transceivers, transmitters, receives, optical circuits, and/or other types of front end semiconductor devices.

A front end transistor structure may include a plurality of source/drain regions, which may correspond to doped regions of the substrate 106, separated by a channel region in the substrate 106. In some implementations, the source/drain regions are doped with a first type of dopant (e.g., a p-type dopant such as boron (B) and/or gallium (Ga), an n-type dopant such as phosphorous (P) and/or arsenic (As)), and the channel region is doped with a second type of dopant that is different from the first type of dopant. The front end transistor structure may include a gate structure over and/or around the channel region. A gate dielectric layer of the front end transistor structure may be included between the gate structure and the channel region. The gate structure may include a polysilicon gate, a metal gate with a high dielectric constant (high-k) gate dielectric layer such as hafnium oxide (HfOₓ such as HfO₂), and/or another type of gate structure.

A dielectric layer 110 is included over the substrate 106. The dielectric layer 110 includes an interlayer dielectric (ILD) layer, an etch stop layer (ESL), and/or another type of dielectric layer. The dielectric layer 110 includes dielectric material(s) that enable various portions of the substrate 106 and/or the integrated circuit devices 108 to be selectively etched or protected from etching, and/or to electrically isolate the integrated circuit devices 108 in the device layer 102. The dielectric layer 110 includes a silicon nitride (SiₓN_{y}), an oxide (e.g., a silicon oxide (SiOₓ) and/or another oxide material), and/or another type of dielectric material. The dielectric layer 110 may extend in the x-direction and/or in the y-direction in the semiconductor device 100. Contacts 112 (e.g., source/drain contacts, gate contacts) may extend through the dielectric layer 110 and between the integrated circuit devices 108 and the interconnect layer 104. The contacts may electrically connect the integrated circuit devices 108 to the interconnect layer 104. The contacts 112 may include vias, plugs, and/or another type of elongated electrically conductive structures. The contacts 112 may include tungsten (W), cobalt (Co), ruthenium (Ru), titanium (Ti), aluminum (Al), and/or gold (Au), among other electrically conductive materials.

The interconnect layer 104 includes a plurality of dielectric layers (e.g., back end dielectric layers) that are arranged in a direction (e.g., the z-direction) that is approximately perpendicular to the top surface of the substrate 106. The dielectric layers may include ILD layers 114 and ESLs 116 that are arranged in an alternating manner in the z-direction. The ILD layers 114 and the ESLs 116 may extend in the x-direction and/or in the y-direction in the semiconductor device 100.

The ILD layers 114 may each include a low dielectric constant (low-k) oxide material such as silicon oxide (SiOₓ) or undoped silicate glass (USG). Additionally and/or alternatively, the ILD layers 114 may each include a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer 114 includes an extreme low dielectric constant (ELK) dielectric material having a dielectric constant that is less than approximately 2.5. Examples of ELK dielectric materials include carbon doped silicon oxide (C—SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous HSQ, porous methyl silsesquioxane (MSQ), porous polyarylether (PAE), and/or porous silicon oxide (SiOₓ), among other examples.

The ESLs 116 may each include a silicon nitride (SiₓN_{y}), silicon carbide (SiC), silicon oxynitride (SiON), and/or another suitable dielectric material. In some implementations, an ILD layer 114 and an ESL 116 include different dielectric materials to provide etch selectivity to enable various structures to be formed in the interconnect layer 104. For example, the ILD layers 114 may each include a low-k dielectric material such as USG, and the ESLs 116 may each include a high-k dielectric material such as silicon nitride (SiₓN_{y}) or silicon carbide (SiC), such that a dielectric constant of one or more ESLs 116 is greater than a dielectric constant of one or more ILD layers 114. Additionally and/or alternatively, two or more ESLs 116 may include different materials. For example, one or more first ESLs 116 may include silicon nitride (SiₓN_{y}), and one or more second ESLs 116 may include silicon carbide (SiC).

The interconnect layer 104 includes a plurality of conductive structures that are arranged in a plurality of layers. The conductive structures may be electrically coupled and/or physically coupled with one or more of the integrated circuit devices 108 in the device layer 102. The conductive structures provide electrical routing that enables signals and/or power to be provided to and/or from the integrated circuit devices 108.

The layers of conductive structures may include a plurality of layers 118a-118g that are vertically arranged and alternate with a plurality of layers 120a-120f in the z-direction (e.g., vertically alternate). The layers 118a-118g each include a layer of metallization structures 122 (e.g., metal lines), and the layers 120a-120f each include a layer of interconnect structures 124 (e.g., vias).

The layers 118a-118g of metallization structures 122 may be referred to as M-layers. For example, a layer 118a of metallization structures 122 (referred to as a metal-0 (M0) layer) may be located at the bottom of the interconnect layer 104 and may be coupled with the device layer 102. In particular, the metallization structures 122 in the M0 layer may be coupled with the contacts 112 (e.g., a contact layer referred to as “CO”-layer) of the integrated circuit devices 108 in the device layer 102. A layer 118b of metallization structures 122 (referred to as a metal-1 layer (M1) layer) may be located above the layer 118a of metallization structures 122 in the interconnect layer 104, a layer 118c of metallization structures 122 (referred to as a metal-2 layer (M2) layer) may be located above the layer 118b of metallization structures 122, and so on.

A layer 120a of interconnect structures 124 (referred to as a via-1 (V0) layer) may be included between the M0 layer and the M1 layer to interconnect the M0 layer and the M1 layer, a layer 120b of interconnect structures 124 (referred to as a via-2 (V1) layer) may be included between the M1 layer and the M2 layer to interconnect the M1 layer and the M2 layer, and so on.

The metallization structures 122 may include a combination of trenches, metallization layers, conductive traces, and/or other types of conductive structures. The interconnect structures 124 may include a combination of vias, interconnects, and/or other types of conductive structures. The metallization structures 122 and the interconnect structures 124 may include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers are included between the dielectric layers of the interconnect layer 104 and the metallization structures 122, and/or between the dielectric layers of the interconnect layer 104 the interconnect structures 124. The one or more liner layers may include barrier liners, adhesion liners, and/or another type of liners. Examples of materials for the one or more liners include tantalum nitride (TaN) and/or titanium nitride (TiN), among other examples.

In some implementations, the topmost layer of conductive structures (e.g., a topmost layer of metallization structures 122, a topmost layer of interconnect structures 124) may be coupled to connection structures at the top of the semiconductor device 100. The connection structures may include solder balls, solder bumps, contact pads (e.g., land grid array (LGA) pads), contact pins (e.g., pin grid array (PGA) pins), under bump metallization (UBM) connections, microbumps, ball grid array (BGA) balls, controlled collapse chip connection (C4) bumps, and/or other types of connection structures. In some implementations, the topmost layer of conductive structures (e.g., a topmost layer of metallization structures 122, a topmost layer of interconnect structures 124) may be coupled to bonding structures, such as bonding pads and/or bonding vias.

As further shown in FIG. 1A, the semiconductor device may be divided into a memory region 126 and a logic region 128. The memory region 126 may include memory devices and corresponding circuitry. The memory devices may include MRAM devices, PC-RAM devices, and/or RRAM devices, among other examples of devices used for memory storage. The logic region 128 may include logic devices and corresponding circuitry to process data and perform computations. The logic devices may include transistors arranged to perform designated algorithms. A semiconductor structure 130 including a plurality of memory devices 132a, 132b, and 132c is included in the interconnect layer 104 of the semiconductor device 100. The semiconductor structure 130 may extend through and/or is included in one or more dielectric layers in the interconnect layer 104, such as one or more ILD layers 114 and/or one or more ESLs 116. In some implementations, an integrated circuit device 108 is electrically coupled to one or more of the memory devices 132a-132c to form a memory cell (e.g., an MRAM cell or another type of resistance-based memory cell) in the semiconductor device 100. In some implementations, a memory device 132a, 132b, and/or 132c is a non-volatile memory device configured to store data in the absence of power. In some implementations, a memory device 132a, 132b, and/or 132c is configured to perform another function in the semiconductor device 100.

FIG. 1B is a diagram of the semiconductor structure 130. As shown in FIG. 1B, each memory device 132a-132c includes a stacked structure with a bottom electrode layer 134, an MTJ structure 136 on the bottom electrode layer 134, and a top electrode layer 138 on the MTJ structure 136. The MTJ structure 136 may include a fixed layer and a free layer (e.g., ferromagnetic layers), separated by a tunnel barrier layer, that selectively allow quantum tunneling of electrons. The free and fixed layers may include ferrous materials including a combination of iron (Fe) and one or more of cobalt (Co), boron (B), and/or nickel (Ni), among other examples, and the tunnel barrier layer may include a crystalline material, such as magnesium oxide (MgO) and/or another suitable material. In operation, a magnetic direction associated with the free layer may be aligned in parallel with a magnetic direction associated with the fixed layer to place the MTJ structure 136 into an ON or 1 state, in which quantum tunneling is allowed, and the MTJ structure 136 exhibits a lower resistance. On other hand, the magnetic direction associated with the free layer may be reversed (that is, anti-parallel) relative to the magnetic direction associated with the fixed layer, to place the MTJ structure 136 into an OFF or 0 state, in which quantum tunneling is disallowed, and the MTJ structure 136 exhibits a higher resistance.

The bottom electrode layer 134 is a bottom electrode of each memory device 132a-132c, and the top electrode layer 138 is a top electrode of each memory device 132a-132c. The bottom electrode layer 134 and the top electrode layer 138 may include one or more electrically conductive materials. Examples include metals such as molybdenum (Mo), nickel (Ni), iridium (Ir), and chromium (Cr), as well as metal nitrides such as titanium nitride (TiN) or tantalum nitride (TaN), among other examples.

First spacer layers 140 are disposed on and along side surfaces of the bottom electrode layer 134, the MTJ structure 136, and a portion of the top electrode layer 138 for each of the memory devices 132a-132c. As shown in FIG. 1B, the first spacer layers 140 may extend below a bottom edge of the bottom electrode layer 134. The first spacer layers 140 may be in direct physical contact with side surfaces of the bottom electrode layer 134, the MTJ structure 136, and the portion of the top electrode layer 138. The first spacer layers 140 may include a dielectric material such as a nitride (e.g., a silicon nitride (SiₓN_{y}) and/or another nitride material), and/or another suitable material. The first spacer layers 140 may protect the MTJ structure 136 from moisture.

Second spacer layers 142 are disposed on side surfaces of the first spacer layers 140, and on side surfaces of part of top electrode layer 138. As shown in FIG. 1B, the second spacer layers 142 may extend below a bottom edge of the bottom electrode layer 134 and/or below bottom edges of the first spacer layers 140. The second spacer layers 142 may be in direct physical contact with the side surfaces of the first spacer layers 140, and the side surfaces of the part of the top electrode layer 138. The second spacer layers 142 may include a dielectric material such as an oxide (e.g., a silicon oxide (SiOₓ), an aluminum oxide (AlₓO_{y}), and/or another oxide material), and/or another suitable material. The second spacer layers 142 may protect the MTJ structure 136 and other layers under the second spacer layers 142 from chemical damage.

The memory devices 132a-132c may be electrically coupled and/or physically coupled to a bottom interconnect structure 144 (e.g., via). The bottom interconnect structures 144 may each include one or more conductive structures in the interconnect layer 104, where the conductive structures include a fill layer 146 and a liner layer 148. The fill layers 146 may include tungsten (W), cobalt (Co), ruthenium (Ru), titanium (Ti), aluminum (Al), copper (Cu), gold (Au), and/or a combination thereof, among other examples of electrically conductive materials. The liner layers 148, which are included on side and bottom surfaces of the bottom interconnect structures 144, are disposed between the dielectric layers of the interconnect layer 104 and the fill layers 146, and/or between a metallization structure 122 under a bottom interconnect structure 144 and the fill layer 146. The liner layers 148 may include barrier liners, adhesion liners, and/or another type of liners. Examples of materials for the liner layers 148 include tantalum nitride (TaN) and/or titanium nitride (TiN), among other examples. The bottom interconnect structures 144 may each be formed in and/or through one or more of the ILD layers 114 and/or ESLs 116.

In some implementations, each of the bottom interconnect structures 144 is disposed under a bottom electrode layer 134 in the z-direction, and is in direct physical contact with a bottom surface of the bottom electrode layer 134.

FIG. 1C is a diagram of an example implementation 150 of a portion of the semiconductor device 100 including the semiconductor structure 130. As shown in FIG. 1C, the semiconductor device is divided into a memory region 126 and a logic region 128. The semiconductor device 100 includes ILD layers 114a, 114b, 114c, and 114d, and ESLs 116a, 116b, 116c, and 116d. The semiconductor device 100 further includes metallization structures 122a, 122b, 122c, 122d, and 122e in ILD layer 114a, metallization structures 122f, 122g, 122h, 122i, and 122j in ILD layer 114b, metallization structures 122k and 122l in ILD layer 114c, and metallization structures 122m and 122n in ILD layer 114d. Metallization structures in the same ILD layer may be in the same metallization layer (e.g., one of layers 118a-g), and may have top surfaces that are coplanar with each other.

An interconnect structure 124a is disposed between and connects metallization structures 122a and 122f. An interconnect structure 124b is disposed between and connects metallization structures 122b and 122g. An interconnect structure 124c is disposed between and connects metallization structures 122c and 122h. An interconnect structure 124d is disposed between and connects metallization structures 122d and 122i. An interconnect structure 124e is disposed between and connects metallization structures 122e and 122j. The interconnect structures 124a-124e are disposed through part of ILD layer 114a and through ESL 116a. An interconnect structure 124f is disposed between and connects metallization structures 122i and 122k. An interconnect structure 124g is disposed between and connects metallization structures 122j and 122l. The interconnect structures 124f and 124g are disposed through part of ILD layer 114b and through ESL 116b. An interconnect structure 124h is disposed between and connects a top electrode layer 138 of a memory device 132a and metallization structure 122m. An interconnect structure 124i is disposed between and connects a top electrode layer 138 of a memory device 132b and metallization structure 122m. An interconnect structure 124j is disposed between and connects a top electrode layer 138 of a memory device 132c and metallization structure 122m. An interconnect structure 124k is disposed between and connects metallization structures 122k and 122n. An interconnect structure 124l is disposed between and connects metallization structures 122l and 122n. The interconnect structures 124h-124l are disposed through part of ILD layer 114c and through ESL 116c.

The bottom interconnect structures 144 of the semiconductor structure 130 respectively land on the metallization structures 122f, 122g, and 122h to connect respective bottom electrode layers 134 to the respective metallization structures 122f, 122g, and 122h. Each bottom interconnect structure 144 is formed in a portion of the ILD layer 114c, through a bottom surface of the ILD layer 114c, and through the ESL 116c.

In the example implementation 150, an oxide layer 152 (e.g., an aluminum oxide (AlₓO_{y}) layer) may be disposed on the ESL 116b in the memory region 126, such that the bottom interconnect structures 144 may also be disposed through the oxide layer 152. A dielectric layer 154 (e.g., USG) may be disposed on the oxide layer 152, and around the bottom interconnect structures 144. The first and second spacer layers 140 and 142 may be conformally disposed on the dielectric layer 154. A plasma-enhanced atomic layer deposition (PEALD) oxide layer 156 may be disposed around the memory devices 132a-132c on the second spacer layers 142. Some examples of PEALD oxides include a zinc oxide (e.g., ZnO), an aluminum oxide (e.g., AlₓO_{y}), an aluminum-zinc oxide (e.g., Al—ZnO), a titanium oxide (e.g., TiOₓ), among other examples. A dielectric layer 158 may be disposed on the ESL 116c, such that the interconnect structures 124h-124l are also disposed through part of the dielectric layer 158. In some implementations, the dielectric layer 158 includes USG.

In some implementations, a horizontal (e.g., lateral) dimension D1 (e.g., x-direction dimension) of each interconnect structure 124h-124j may be smaller than a horizontal (e.g., lateral) dimension D2 (e.g., x-direction dimension) of each interconnect structure 124k and 124l. The smaller horizontal dimension D1 may be due to a smaller lateral footprint of each of the memory devices 132a-132c and a smaller pitch between the memory devices 132a-132c than other memory devices. For example, the memory devices 132a-132c may be designed in accordance with a 5 nm node and beyond, where a pitch between the memory devices 132a-132c is less than approximately 42 nanometers.

In some implementations, a vertical dimension D3 (e.g., z-direction dimension) (e.g., height or depth) of each interconnect structure 124h-124j may be greater than a vertical dimension D4 (e.g., z-direction dimension) of each interconnect structure 124k and 124l. The greater vertical dimension D3 may be due to a top surface of the top electrode layer 138 of each of the memory devices 132a-132c failing to reach a top surface of the ILD layer 114c and/or a bottom surface of the ESL 116c. As a result, the interconnect structures 124h-124j may be formed through a top portion of the ILD layer 114c to land on the top electrode layer 138 of each of the memory devices 132a-132c. In some implementations, the vertical dimension D3 of the interconnect structures 124h-124j may be approximately 100 angstroms to approximately 300 angstroms greater than the vertical dimension D4 of the interconnect structures 124k and 124l. Alternatively, the vertical dimension D3 of each of the interconnect structures 124h-124j may be equal to the vertical dimension D4 of the interconnect structures 124k and 124l. In the case where the vertical dimensions D3 and D4 are equal, the top surfaces of the top electrode layer 138 of each of the memory devices 132a-132c may be co-planar with or approximately co-planar with top surfaces of the metallization structures 122k and 122l.

The metallization structure 122m is commonly connected to the top electrode layer 138 of each memory device 132a, 132b, and 132c through the interconnect structures 124h, 124i, and 124j, respectively. The interconnect structures 124h, 124i, and 124j, which are in direct contact with a surface of the top electrode layer 138 of memory devices 132a, 132b, and 132c, respectively, are commonly connected to the metallization structure 122m. In some implementations, the surface of the top electrode layer 138 of each memory device 132a, 132b, and 132c with which the interconnect structures 124h, 124i, and 124j are in direct contact is curved. A top surface of the metallization structure 122m may be co-planar with or approximately co-planar with a top surface of the metallization structure 122n.

The semiconductor structure 130 includes three memory devices 132a, 132b, and 132c. Alternatively, the semiconductor structure 130 may include more or fewer than three memory devices.

As indicated above, FIGS. 1A-1C are provided as examples. Other examples may differ from what is described with regard to FIGS. 1A-1C.

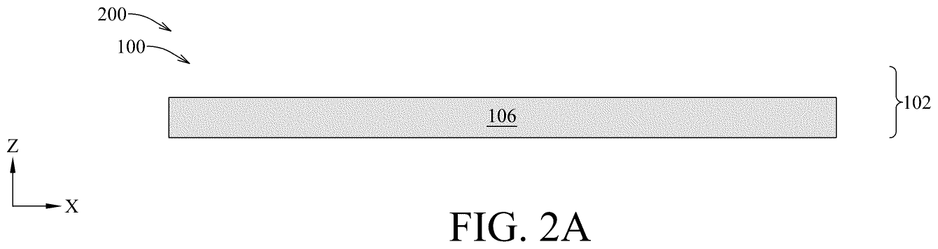

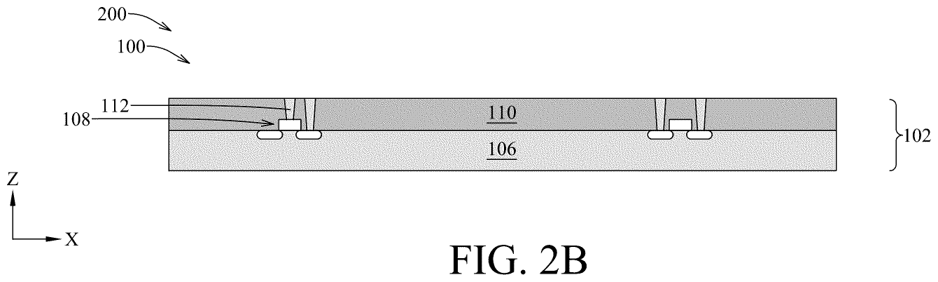

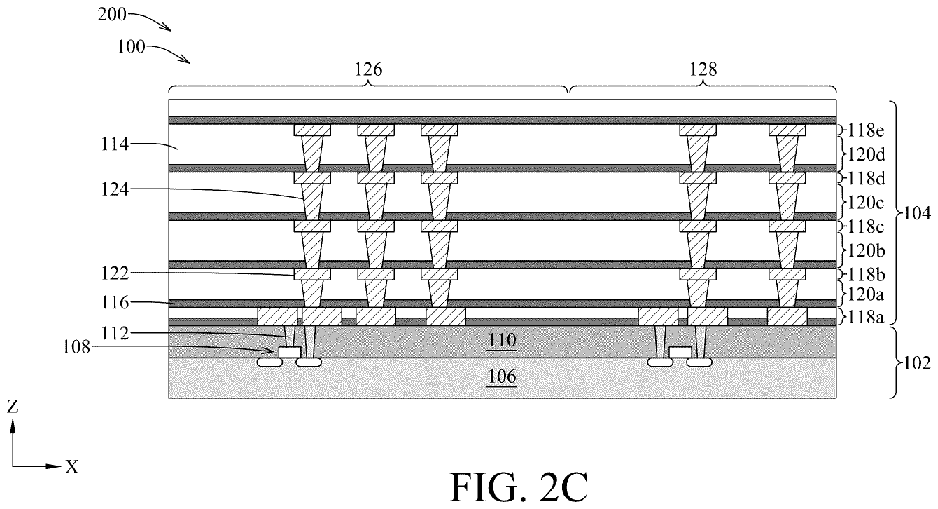

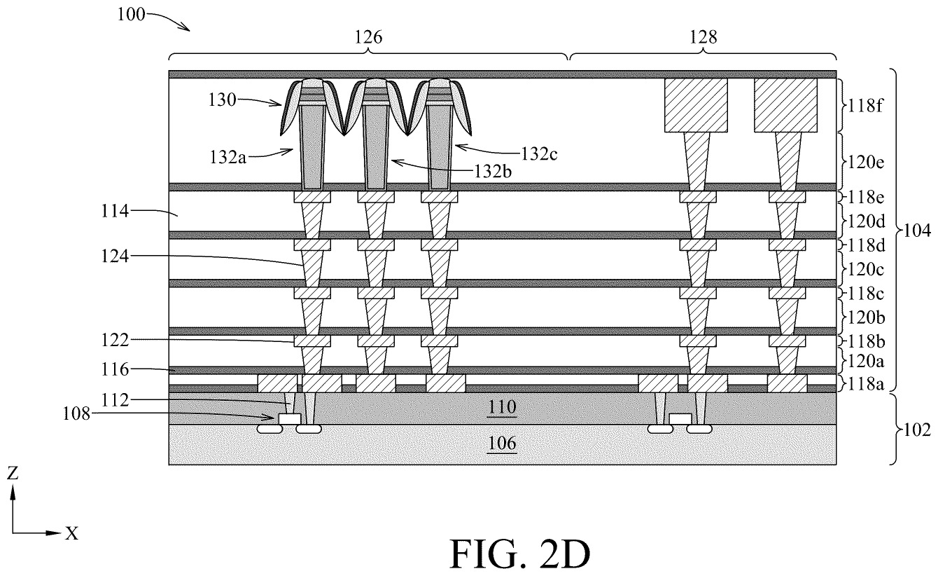

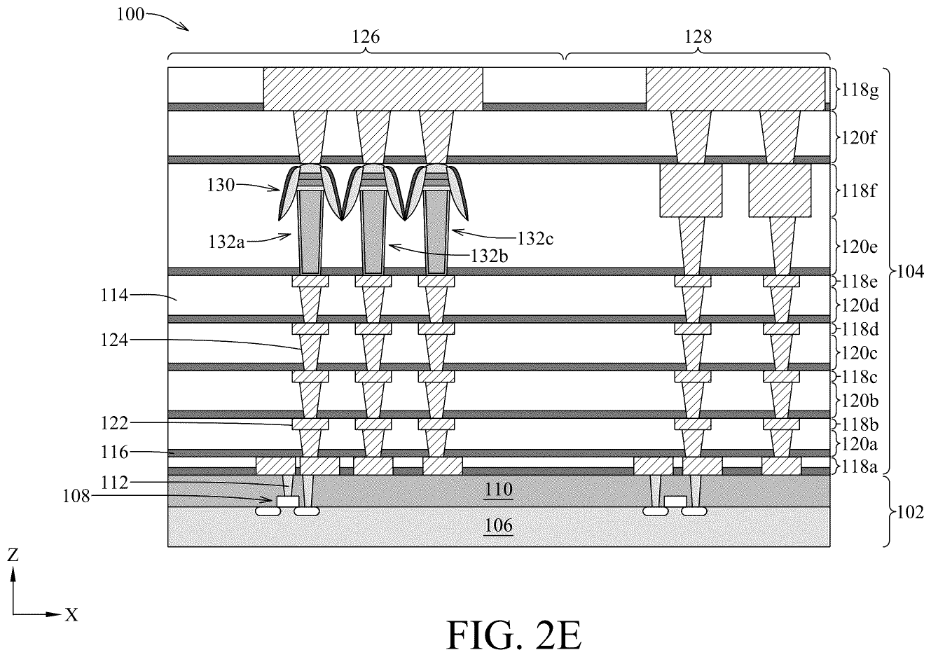

FIGS. 2A-2E are diagrams of an example implementation 200 of forming the semiconductor device 100 described herein. In some implementations, one or more of the semiconductor processing operations described in connection with FIGS. 2A-2E may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

Turning to FIG. 2A, the substrate 106 is provided. The substrate 106 may be provided in the form of a semiconductor wafer such as a silicon (Si) wafer, an SOI wafer, and/or another type of semiconductor work piece. The semiconductor device 100 may be formed on the semiconductor wafer with other semiconductor devices.

As shown in FIG. 2B, the integrated circuit devices 108 may be formed in and/or on the substrate 106 in the device layer 102 of the semiconductor device 100. One or more semiconductor processing tools may be used to form one or more portions of the integrated circuit devices 108. For example, an ion implantation tool may be used to dope one or more regions in the substrate 106 with one or more types of dopants to form well regions, implant regions, and/or other types of doped regions in the substrate 106 for the integrated circuit devices 108. As another example, a deposition tool may be used to perform various deposition operations to deposit layers and/or structures of the integrated circuit devices 108, and/or to deposit photoresist layers for etching the substrate 106 and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the substrate 106 and/or portions of the deposited layers to form the integrated circuit devices 108. As another example, a planarization tool may be used to planarize portions of the integrated circuit devices 108. As another example, a plating tool may be used to deposit metal structures and/or layers of the integrated circuit devices 108.

As further shown in FIG. 2B, a deposition tool is used to deposit the dielectric layer 110 over and/or on the substrate 106 and over and/or on the integrated circuit devices 108. A deposition tool may be used to deposit the dielectric layer 110 using a physical vapor deposition (PVD) technique, an atomic layer deposition (ALD) technique, a chemical vapor deposition (CVD) technique, an oxidation technique, and/or another suitable deposition technique. In some implementations, a planarization tool may be used to perform a planarization operation such as a chemical mechanical planarization (CMP) operation to planarize the dielectric layer 110 after the dielectric layer 110 is deposited.

As further shown in FIG. 2B, the contacts 112 of the integrated circuit devices 108 may be formed through the dielectric layer 110. The contacts 112 may be formed in recesses in the dielectric layer 110. In some implementations, a pattern in a photoresist layer is used to etch the dielectric layer 110 to form the recesses. In these implementations, a deposition tool may be used to form the photoresist layer on the dielectric layer 110. An exposure tool may be used to expose the photoresist layer to a radiation source to pattern the photoresist layer. A developer tool may be used to develop and remove portions of the photoresist layer to expose the pattern. An etch tool may be used to etch the dielectric layer based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 110 based on a pattern to form the recesses.

The contacts 112 may be formed in the recesses. In some implementations, a contact 112 (e.g., a gate contact) is formed on a gate structure of an integrated circuit device 108. In some implementations, a contact 112 (e.g., a source/drain contact) is formed on a source/drain region of an integrated circuit device 108. A deposition tool may be used to deposit the material of the contacts 112 in the recesses using a CVD technique, a PVD technique, an ALD technique, an electroplating technique, and/or another suitable deposition technique. The material of the contacts 112 may be deposited in one or more deposition operations. In some implementations, a seed layer is first deposited, and the material of the contacts 112 is deposited on the seed layer. In some implementations, a planarization tool is used to perform a planarization operation (e.g., a CMP operation) to planarize the contacts 112 after the contacts 112 are deposited such that the tops of the contacts 112 are approximately co-planar with the top of the dielectric layer 110.

As shown in FIG. 2C, a first portion of the interconnect layer 104 of the semiconductor device 100 is formed above the dielectric layer 110. One or more deposition tools are used to deposit alternating layers of ILD layers 114 and ESLs 116 in the first portion of the interconnect layer 104 of the semiconductor device 100. In this way, the ILD layers 114 and ESLs 116 may be arranged in the z-direction in the semiconductor device 100. One or more deposition tools may be used to deposit each of the ILD layers 114 and each of the ESLs 116 using a PVD technique, an ALD technique, a CVD technique, an oxidation technique, and/or another suitable deposition technique. In some implementations, a planarization tool may be used to planarize the ILD layers 114 and/or the ESLs 116 after the ILD layers 114 and/or the ESLs 116 are deposited.

As further shown in FIG. 2C, a deposition tool, an exposure tool, a developer tool, an etch tool, a planarization tool, a plating tool, and/or another semiconductor processing tool may be used to perform various operations to form the metallization structures 122 and to form the interconnect structures 124 in the memory region 126 and the logic region 128 in the first portion of the interconnect layer 104 of the semiconductor device 100.

In some implementations, the first portion of the interconnect layer 104 may be formed in a plurality of layers. For example, an ILD layer 114 and an ESL 116 may be formed (e.g., using one or more deposition tools and/or one or more planarization tools), recesses may be formed in and/or through the ILD layer 114 and the ESL 116 (e.g., using an exposure tool, a developer tool, and/or an etch tool), and the layer 118a (e.g., the M0 layer) of metallization structures 122 may be formed in the ILD layer 114 and the ESL 116 (e.g., using one or more deposition tools and/or one or more planarization tools). Another ILD layer 114 and another ESL 116 may be formed, and the layer 120a (e.g., the V0 layer) of interconnect structures 124 may be formed in the ILD layer 114 and the ESL 116. The layers 118b-118g, and 120b-120f may be formed in a similar manner.

One or more deposition tools may be used to deposit the metallization structures 122 and/or the interconnect structures 124 using a PVD technique, an ALD technique, a CVD technique, an electroplating technique (e.g., an electro-chemical plating technique), and/or another suitable deposition technique. In some implementations, a planarization tool may be used to planarize the metallization structures 122 and/or the interconnect structures 124 after the metallization structures 122 and/or the interconnect structures 124 are deposited.

As shown in FIG. 2D, a second portion of the interconnect layer 104 of the semiconductor device 100 is formed above the first portion of the interconnect layer 104. The memory devices 132a-132c and the bottom interconnect structures 144 of the semiconductor structure 130 are formed in the memory region 126 in the second portion of the interconnect layer 104. The second portion includes the layer 120e (e.g., the V4 layer) and the layer 118f (e.g., the M5 layer). The layers 120e and 118f are formed in the logic region 128 in an ILD layer 114 (e.g., ILD layer 114c) over the layer 120d (e.g., the V3 layer) and the layer 118e (e.g., the M4 layer). The layers 120e and 118f are formed in the logic region 128 after the memory devices 132a-132c and the bottom interconnect structures 144 of the semiconductor structure 130 are formed in the memory region 126. The layers 120e and 118f in the logic region 128 may be formed in a similar manner to the layers 120a-120d, and the layers 118a-118e.

As shown in FIG. 2D, the layers 120e and 118f are formed in the logic region 128 on a lateral side of the memory devices 132a-132c in the x-direction. The memory devices 132a-132c are formed in the same ILD layer 114 (e.g., ILD layer 114c) as the layers 120e and 118f. The bottom electrode layer 134, the MTJ structure 136, and the top electrode layer 138 of each of the memory devices 132a-132c are formed over the bottom interconnect structures 144.

The memory devices 132a-132c may be formed such that the bottom electrode layers 134 of the memory devices 132a-132c land on the bottom interconnect structures 144 in the interconnect layer 104.

As shown in FIG. 2E, a remaining part of the second portion of the interconnect layer 104 of the semiconductor device 100 (e.g., layers 118g and 120f) is formed in the memory region 126 and in the logic region 128 above layers 118f and 120e and/or above the memory devices 132a-132c. The layers 120f and 118g may be formed in a similar manner to the layers 120a-120e, and the layers 118a-118f. The interconnect structures 124 in layer 120f in the memory region 126 of the semiconductor device 100 are in direct contact with the top surfaces of the top electrode layers 138 of the memory devices 132a-132c.

As indicated above, FIGS. 2A-2E are provided as an example. Other examples may differ from what is described with regard to FIGS. 2A-2E.

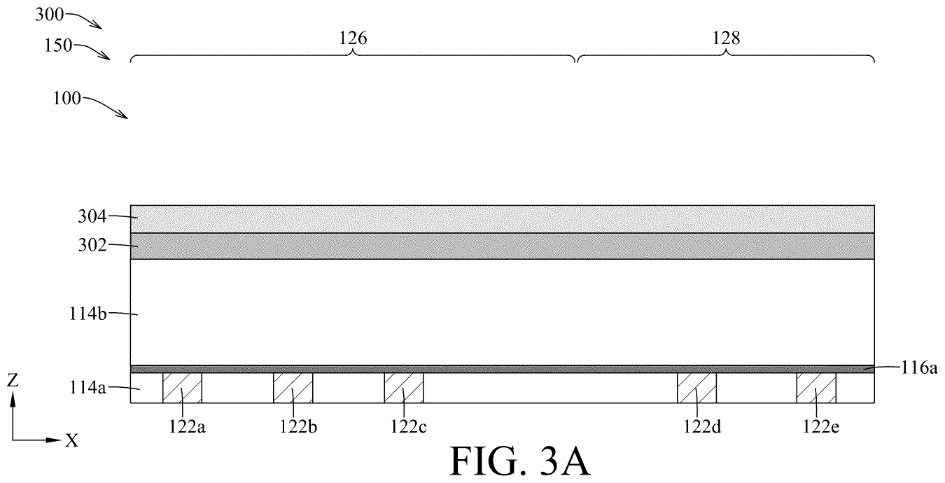

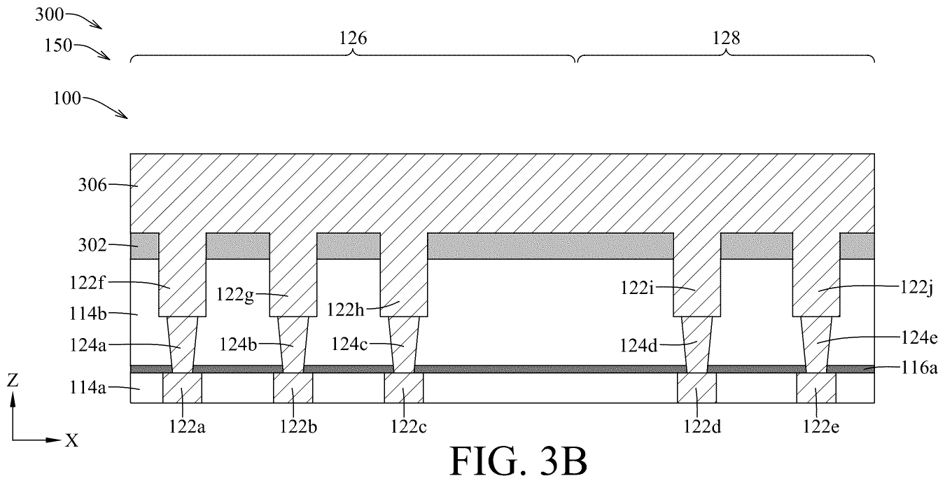

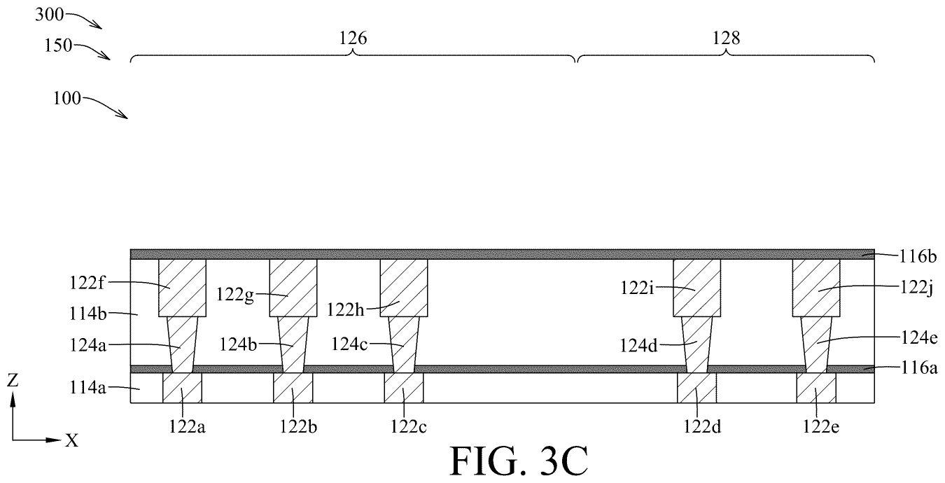

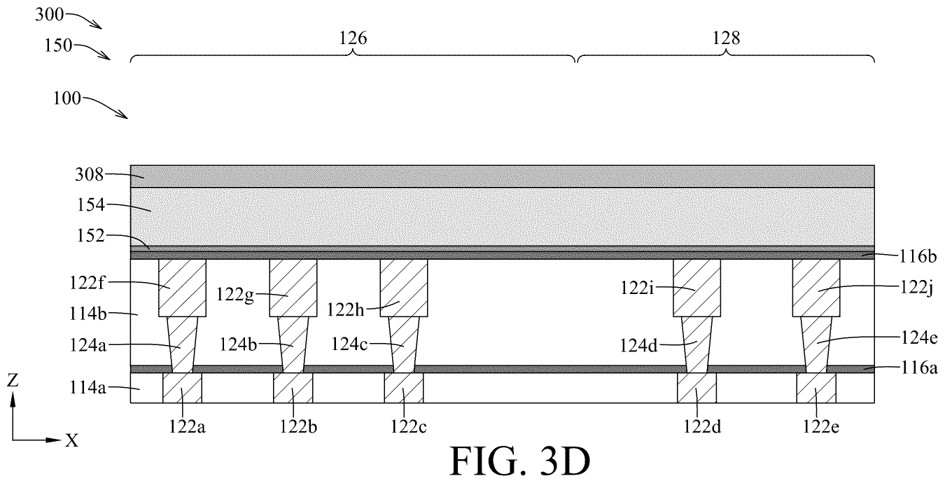

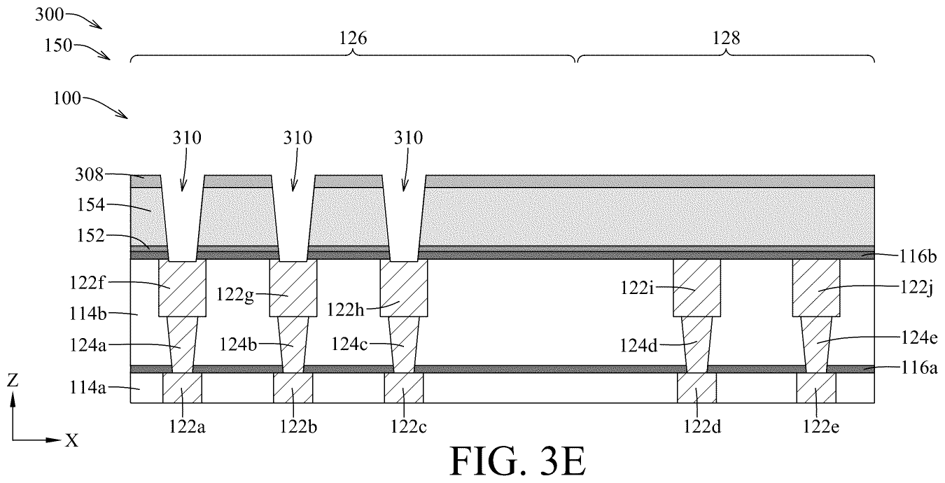

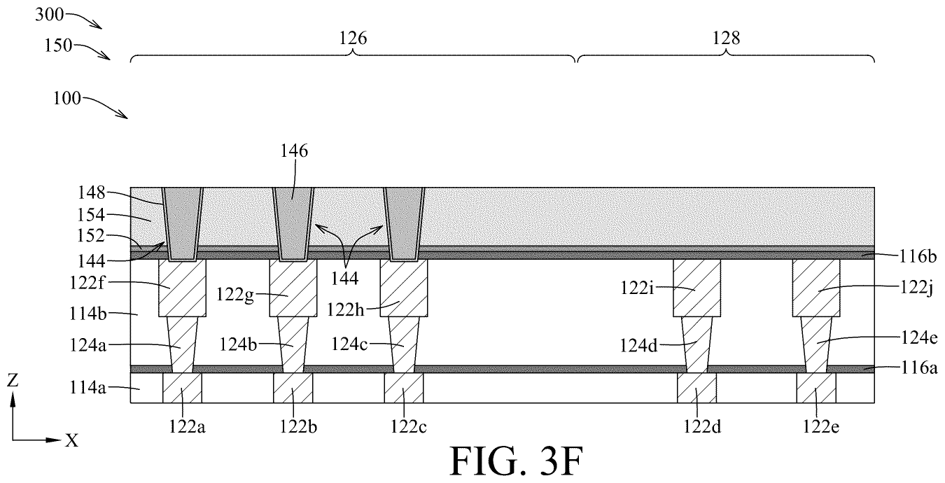

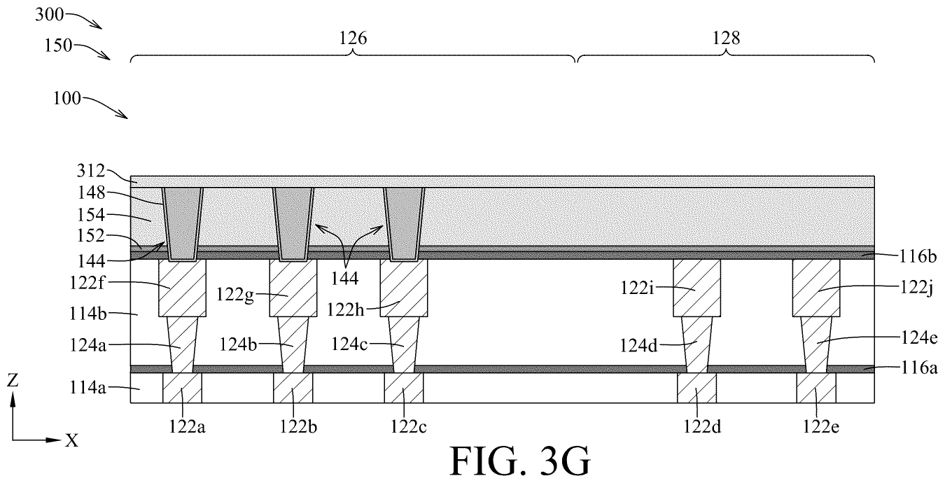

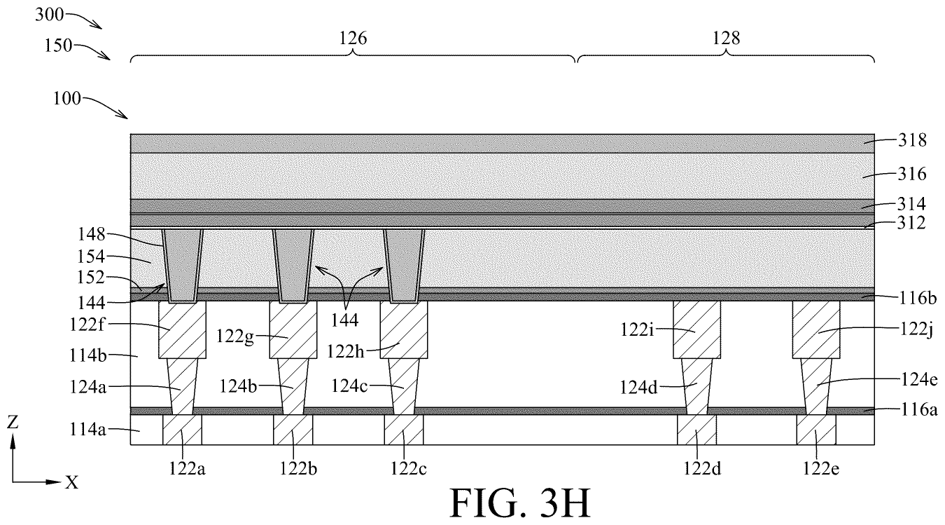

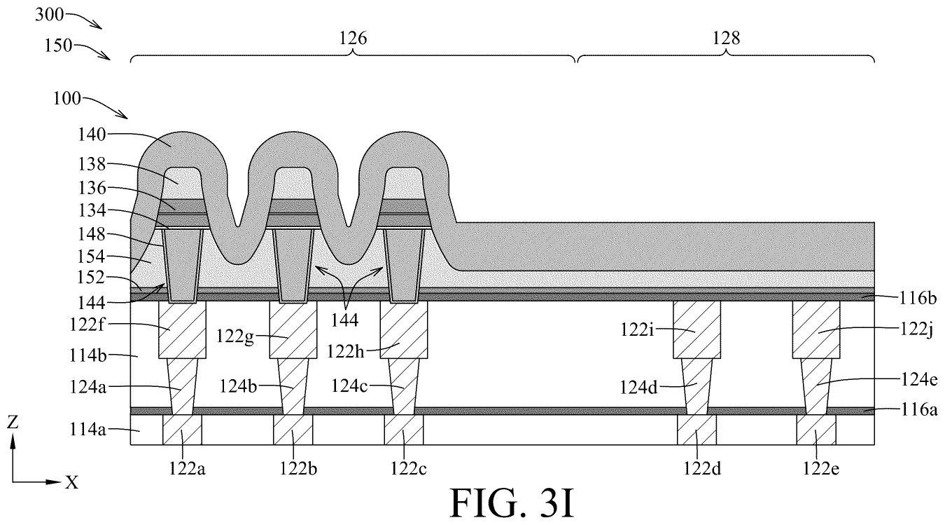

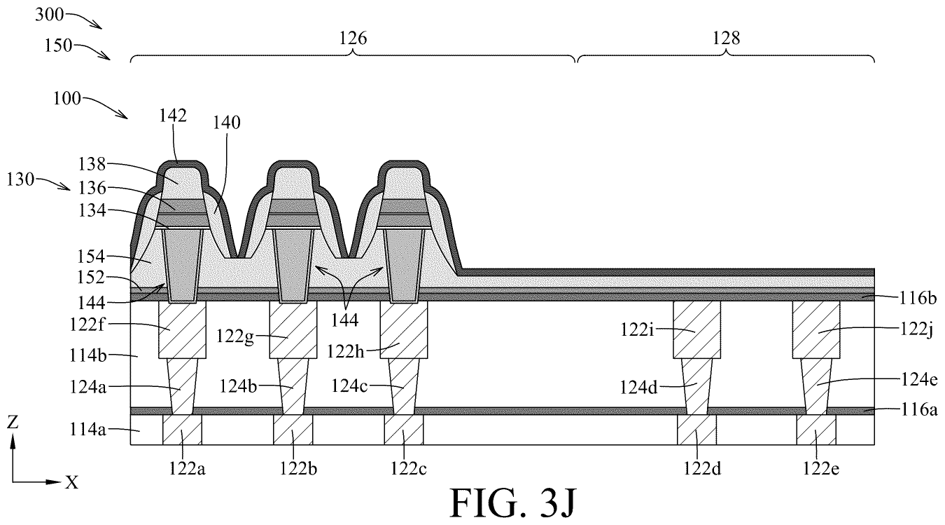

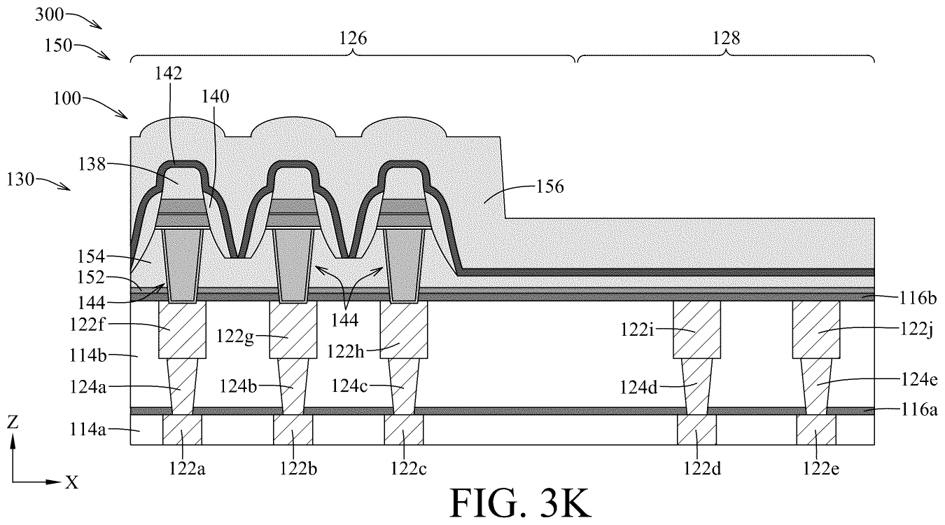

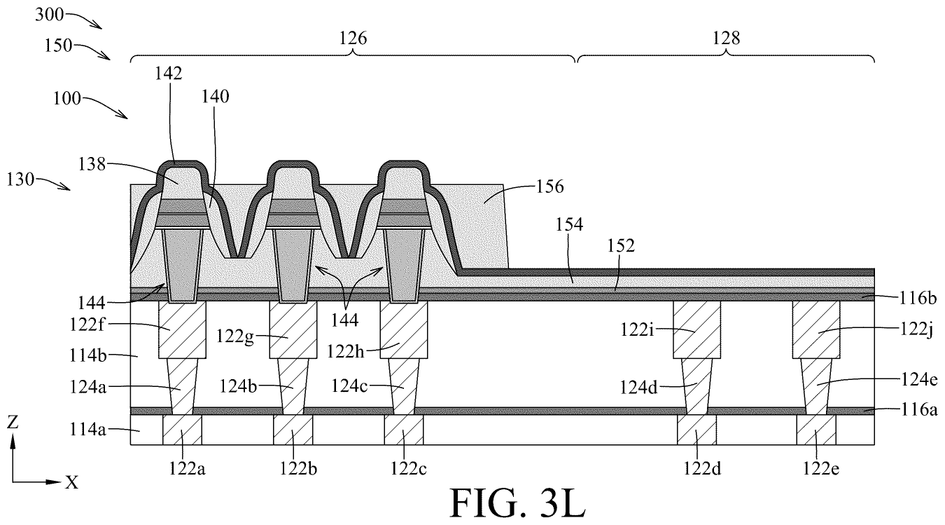

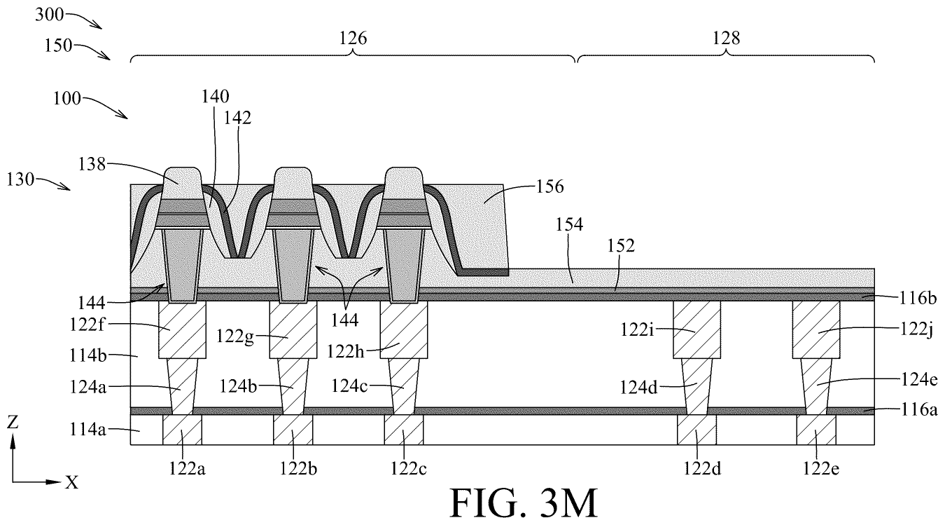

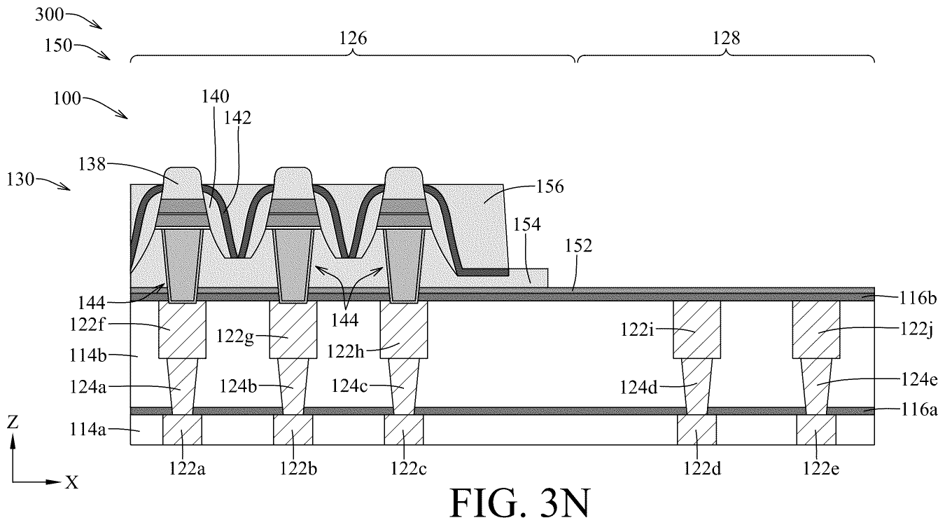

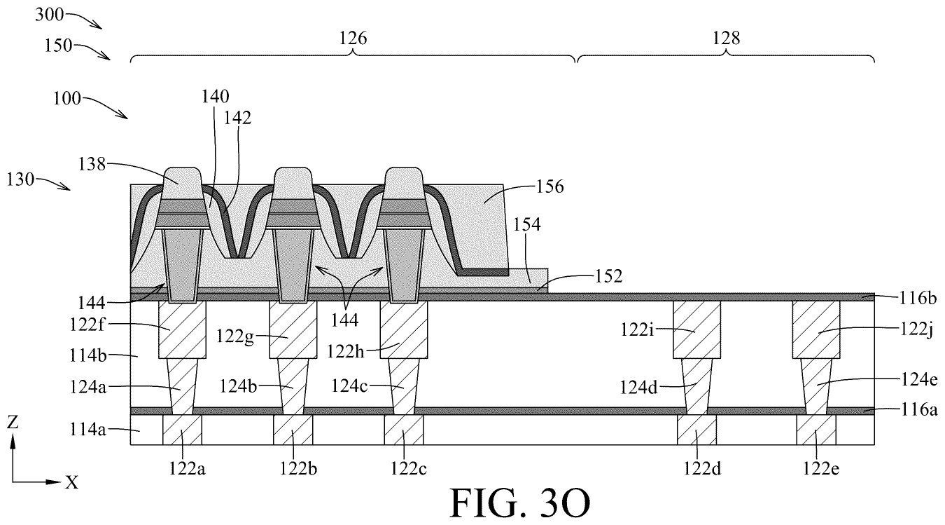

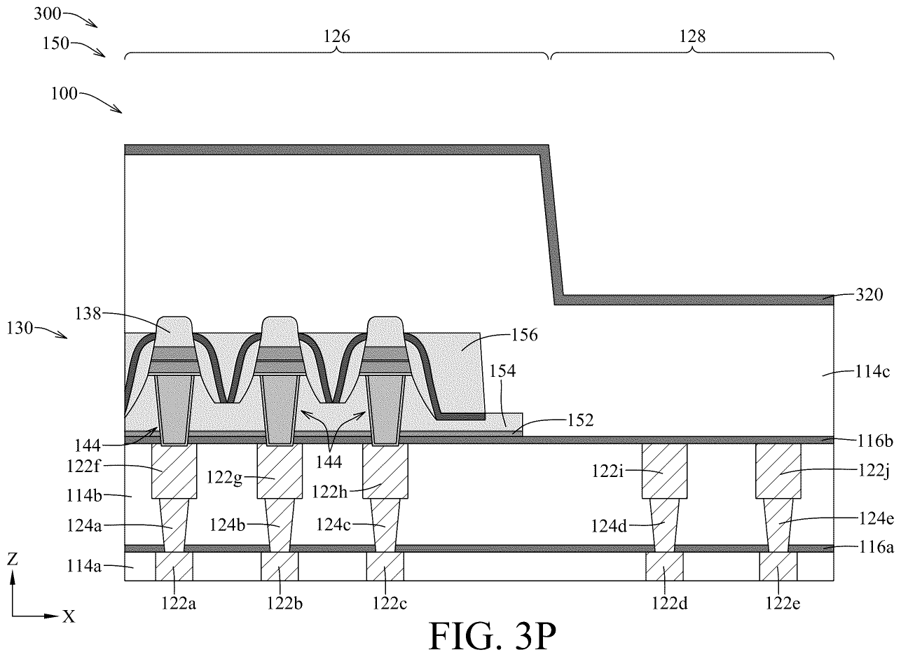

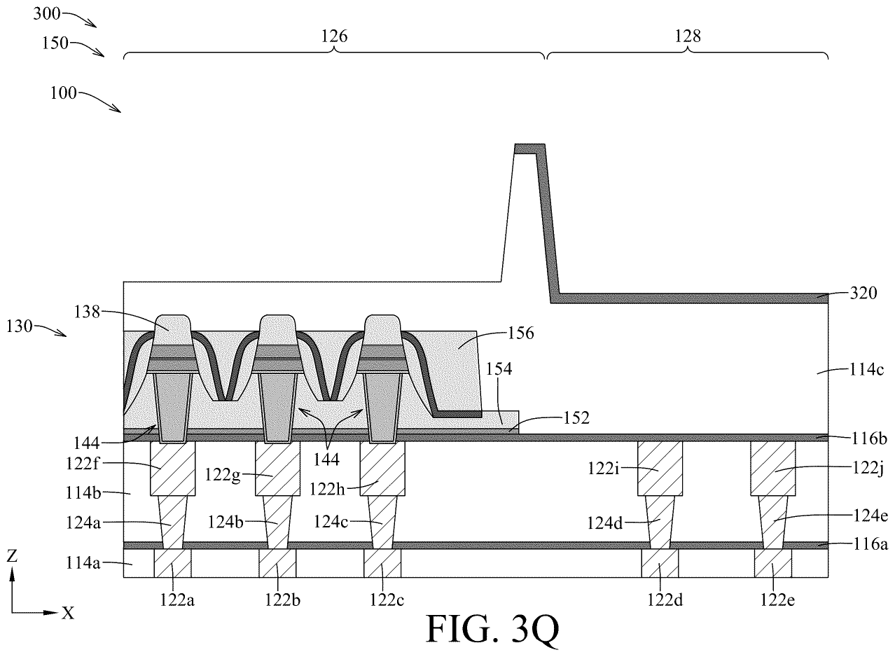

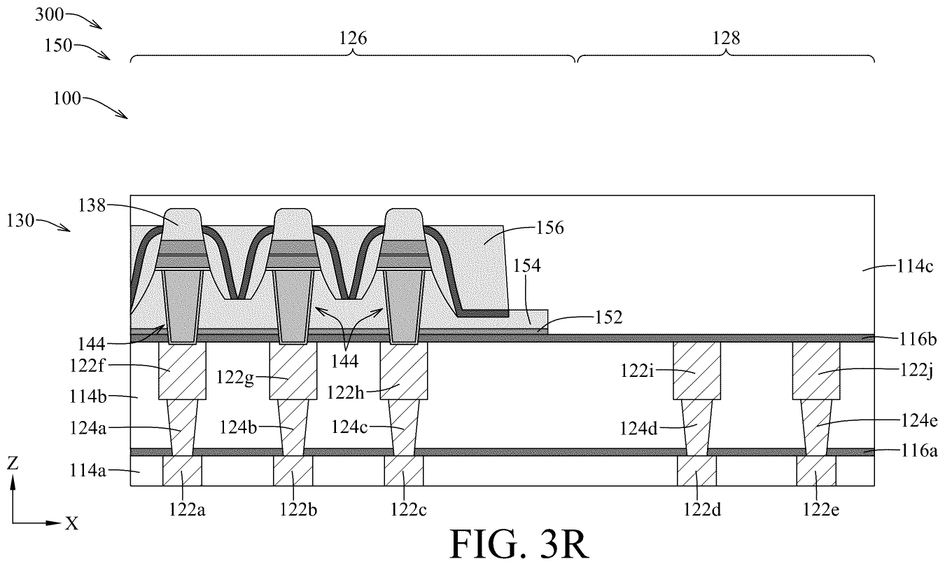

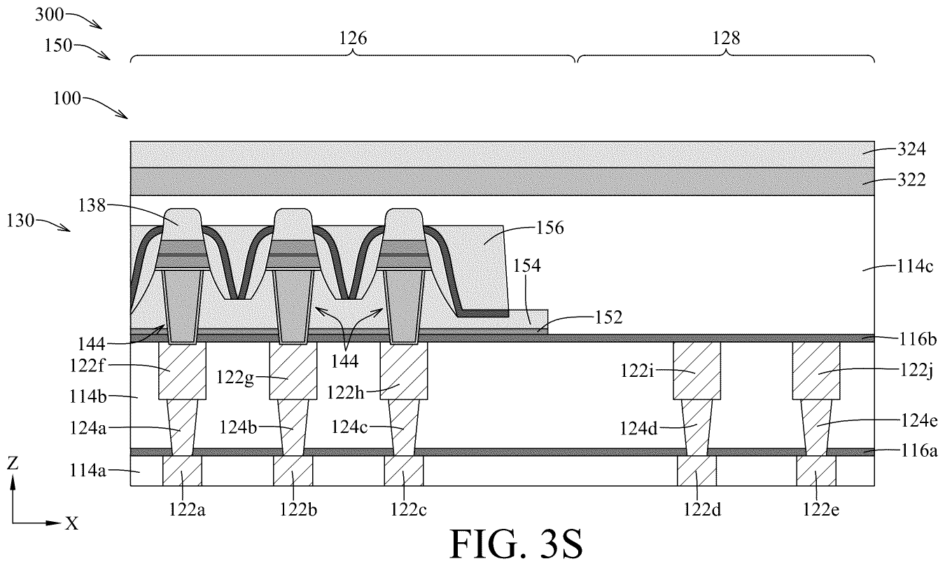

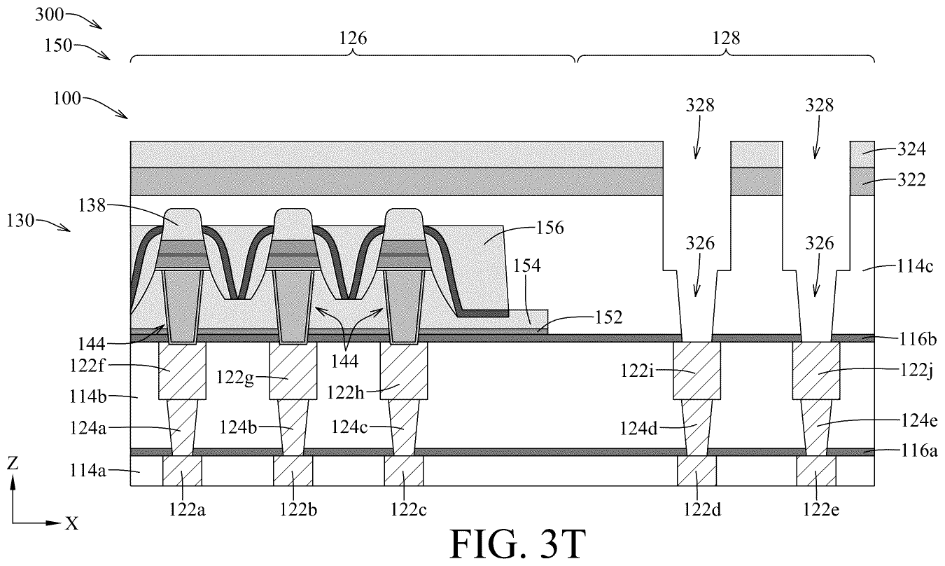

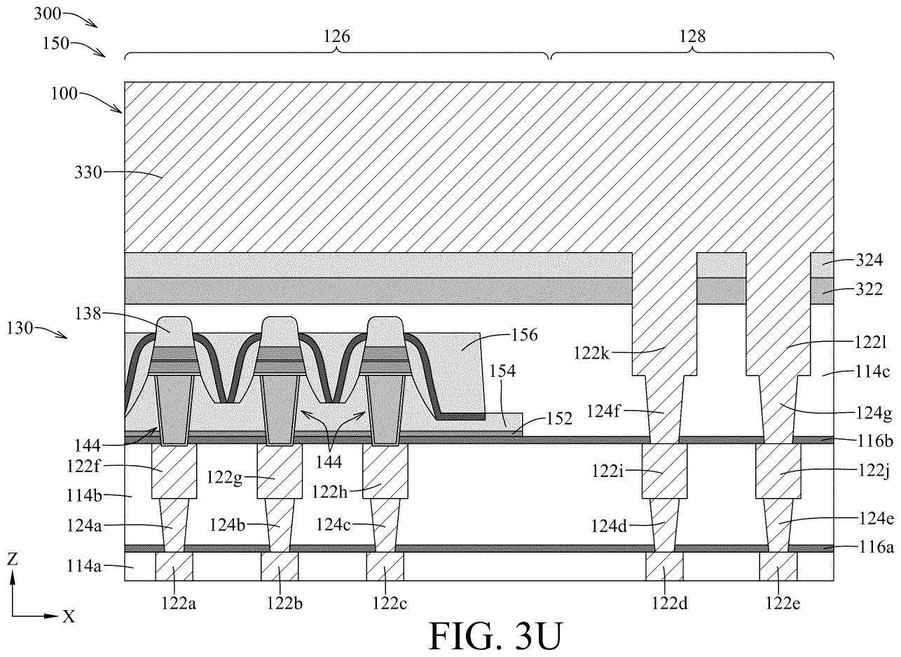

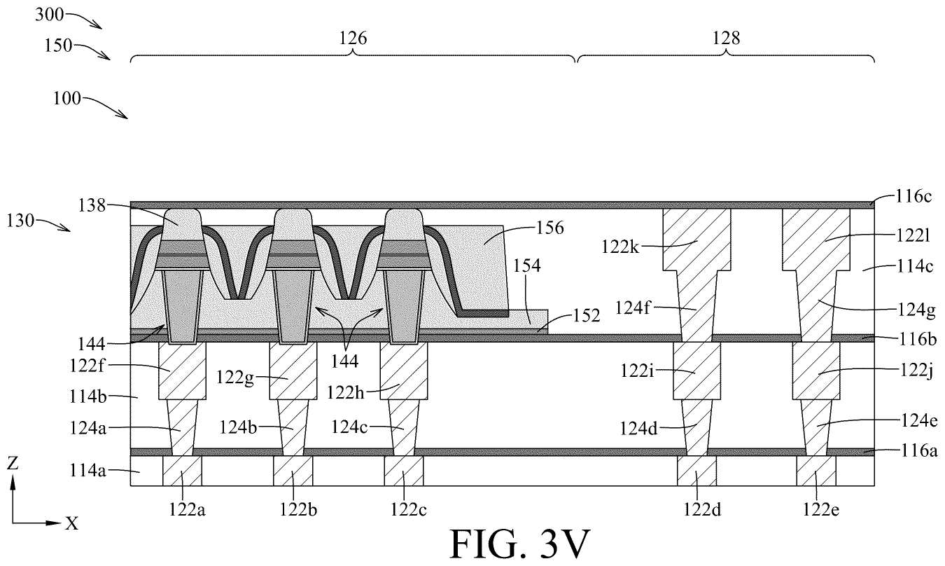

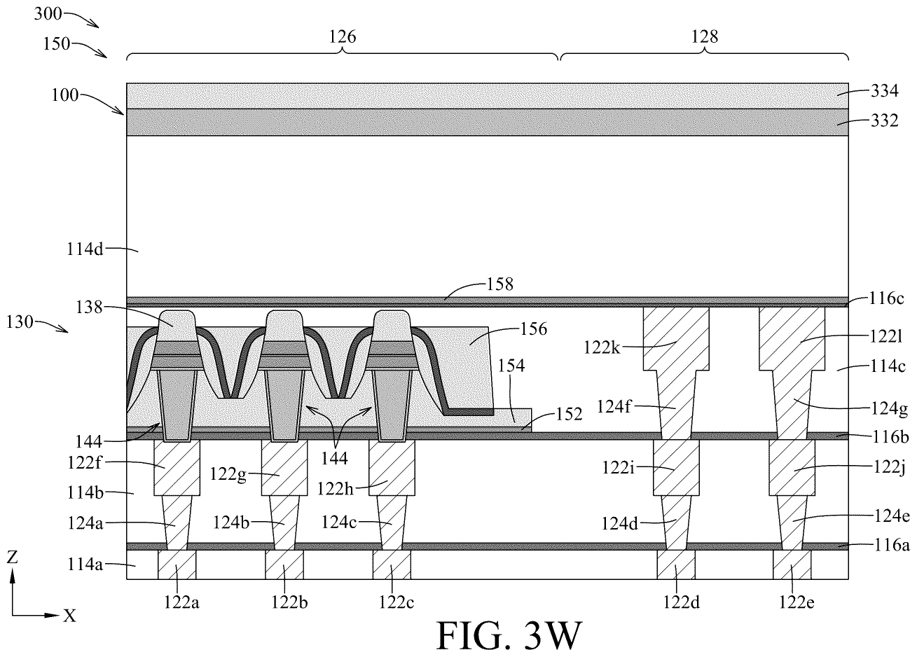

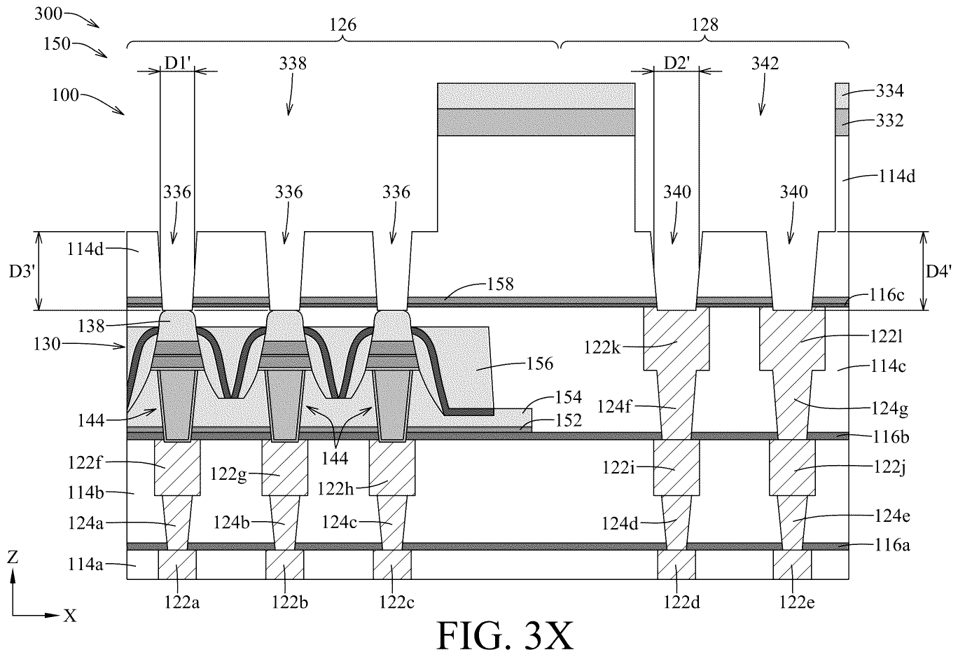

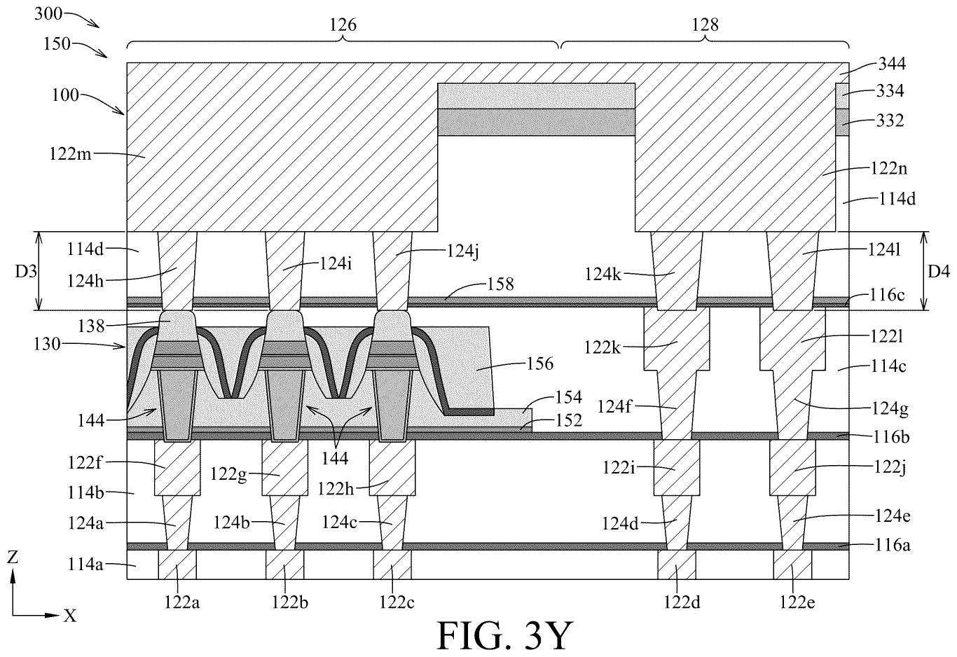

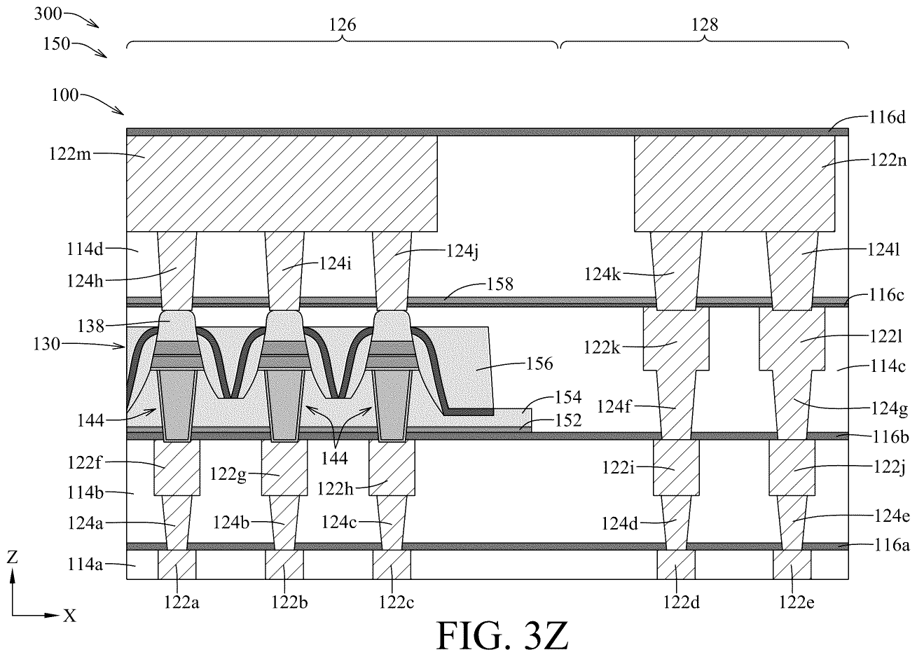

FIGS. 3A-3Z are diagrams of an example implementation 300 of forming a portion of a semiconductor device 100 described herein. In some implementations, one or more of the semiconductor processing operations described in connection with FIGS. 3A-3Z may be performed using one or more semiconductor processing tools, such as a deposition tool, an exposure tool, a developer tool, an etch tool, a planarization tool, a wafer/die transport tool, and/or another type of semiconductor processing tool. In some implementations, one or more of the semiconductor processing operations described in connection with FIGS. 3A-3Z may be performed as part of the process for forming the semiconductor device 100 described in connection with FIGS. 2A-2E.

As shown in FIG. 3A, the ESL 116a and the ILD layer 114b are formed on the layer 118d (e.g., the M3 layer) including the metallization structures 122a-c in the memory region 126, and the metallization structures 122d and 122e in the logic region 128. The ESL 116a is formed over the ILD layer 114a, and the ILD layer 114b is formed on the ESL 116a in the memory region 126 and in the logic region 128. The ESL 116a and the ILD layer 114b may be deposited using a PVD technique, an ALD technique, a CVD technique, an oxidation technique, and/or another suitable deposition technique. In some implementations, a planarization tool may be used to planarize the ESL 116a and/or the ILD layer 114b after the ESL 116a and/or the ILD layer 114b are deposited.

A mask structure including a dielectric masking layer 302 and a photoresist layer 304 may be formed on the ILD layer 114b in the interconnect layer 104 of the semiconductor device 100. For example, a dielectric masking layer 302 may be formed on the ILD layer 114b. The dielectric masking layer 302 may include a silicon oxynitride material (SiON) and/or another suitable dielectric material.

A deposition tool may be used to deposit the dielectric masking layer 302 using a PVD technique, an ALD technique, a CVD technique, an oxidation technique, and/or another suitable deposition technique. In some implementations, a planarization tool is used to perform a planarization operation (e.g., a CMP operation) to planarize the dielectric masking layer 302 after the dielectric masking layer 302 is deposited.

A photoresist layer 304 may be formed above the dielectric masking layer 302, and a pattern may be formed in the photoresist layer 304. A deposition tool may be used to form the photoresist layer 304 on the dielectric masking layer 302 (e.g., using a spin-coating technique or another suitable deposition technique). In some implementations, a bottom antireflective coating (BARC) is first deposited on the dielectric masking layer 302, and then the photoresist layer 304 is deposited onto the BARC. An exposure tool may be used to expose the photoresist layer 304 to a radiation source to pattern the photoresist layer. A developer tool may be used to develop and remove portions of the photoresist layer to expose the pattern.

An etch tool may be used to etch the dielectric masking layer 302 based on the pattern in the photoresist layer 304, to transfer the pattern to the dielectric masking layer 302. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer 304 (e.g., using a chemical stripper, plasma ashing, and/or another technique). The etchant may have a higher etch rate for the dielectric masking layer 302 compared to the material of the underlying ILD layer 114b. Thus, the etch operation may stop on the ILD layer 114b with minimal etching to the ILD layer 114b.

Based on the pattern in the dielectric masking layer 302, one or more additional etch operations may be performed to etch through the ILD layer 114b and the ESL 116a to form recesses in the memory region 126 and in the logic region 128, where bottom surfaces of the recesses expose portions of top surfaces of the underlying metallization structures 122a-122e. The etch operations may include, for example, a gas-based etch operation in which a different type of etchant is used, as compared to the etchant that was used to transfer the pattern to the dielectric masking layer 302. Thus, the semiconductor device 100 may be transferred from a first etch tool (in which the pattern was transferred to the dielectric masking layer 302) to a second etch tool (in which the ILD layer 114b and the ESL 116a are etched) using a wafer/die transport tool to reduce the likelihood of cross-contamination between the first and second etch tools. Alternatively, an etch tool that has multiple processing chambers (e.g., a cluster tool) may be used, and the semiconductor device 100 may be transferred between processing chambers of the etch tool for etching using different types of etchants.

In some implementations, a dual damascene process is used to form the recesses. For example, recesses in which the interconnect structures 124a-124e are to be formed may be formed in and/or through a bottom portion of the ILD layer 114b and ESL 116a. Recesses in which the metallization structures 122f-122j are to be formed may be formed in the top portion of the ILD layer 114b above the recesses in which the interconnect structures 124a-124e are to be formed.

An interconnect structure-first dual damascene procedure can be performed in which the recesses are formed by forming the recesses in which the interconnect structures 124a-124e are to be formed before forming the recesses in which the metallization structures 122f-122j are to be formed. In some implementations, a trench-first dual damascene procedure can be performed in which the recesses in which the metallization structures 122f-122j are to be formed are formed before forming the recesses in which the interconnect structures 124a-124e are to be formed.

As shown in FIG. 3B, one or more deposition tools may be used to deposit conductive material 306 in the recesses to form the metallization structures 122f, 122g, 122h, 122i, and 122j, and the interconnect structures 124a, 124b, 124c, 124d, and 124e, using a PVD technique, an ALD technique, a CVD technique, an electroplating technique (e.g., an electro-chemical plating technique), and/or another suitable deposition technique. As noted herein, the conductive material 306 to form the metallization structures 122f, 122g, 122h, 122i, and 122j and the interconnect structures 124a, 124b, 124c, 124d, and 124e may include, for example, tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers are included in the metallization structures 122f, 122g, 122h, 122i, and 122j and the interconnect structures 124a, 124b, 124c, 124d, and 124e. The one or more liner layers may include barrier liners, adhesion liners, and/or another type of liners. Examples of materials for the one or more liners include tantalum nitride (TaN) and/or titanium nitride (TiN), among other examples. A planarization tool may be used to planarize the surface of the ILD layer 114b to remove the dielectric masking layer 302, and excess portions of the conductive material 306 formed on the dielectric masking layer 302 and/or over the top surfaces of the ILD layer 114b.

As shown in FIG. 3C, an ESL 116b is deposited on the ILD layer 114b following the planarization process. The ESL 116b may be deposited using a PVD technique, an ALD technique, a CVD technique, an oxidation technique, and/or another suitable deposition technique. In some implementations, a planarization tool may be used to planarize the ESL 116b after the ESL 116b is deposited.

As shown in FIG. 3D, the oxide layer 152 (e.g., an aluminum oxide (AlₓO_{y}) layer) may be deposited on the ESL 116b, and the dielectric layer 154 (e.g., USG) may be deposited on the oxide layer 152. The ESL 116b, the oxide layer 152, and the dielectric layer 154 may be deposited using a PVD technique, an ALD technique, a CVD technique, an oxidation technique, and/or another suitable deposition technique. In some implementations, a planarization tool may be used to planarize the ESL 116b, the oxide layer 152, and/or the dielectric layer 154 after the ESL 116b, the oxide layer 152, and/or the dielectric layer 154 are deposited.

A masking layer may be formed on the dielectric layer 154 in the interconnect layer 104 of the semiconductor device 100. For example, a dielectric masking layer 308 may be formed on the dielectric layer 154. The dielectric masking layer 308 may include a silicon oxynitride material (SiON) and/or another suitable dielectric material.

A deposition tool may be used to deposit the dielectric masking layer 308 using a PVD technique, an ALD technique, a CVD technique, an oxidation technique, and/or another suitable deposition technique. In some implementations, a planarization tool is used to perform a planarization operation (e.g., a CMP operation) to planarize the dielectric masking layer 308 after the dielectric masking layer 308 is deposited.

A photoresist layer may be formed above the dielectric masking layer 308, and a pattern may be formed in the photoresist layer. A deposition tool may be used to form the photoresist layer on the dielectric masking layer 308 (e.g., using a spin-coating technique or another suitable deposition technique). In some implementations, a BARC is first deposited on the dielectric masking layer 308, and then the photoresist layer is deposited onto the BARC. An exposure tool may be used to expose the photoresist layer to a radiation source to pattern the photoresist layer. A developer tool may be used to develop and remove portions of the photoresist layer to expose the pattern.

An etch tool may be used to etch the dielectric masking layer 308 based on the pattern in the photoresist layer, to transfer the pattern to the dielectric masking layer 308. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). The etchant may have a higher etch rate for the dielectric masking layer 308 compared to the material of the underlying dielectric layer 154. Thus, the etch operation may stop on the dielectric layer 154 with minimal etching to the dielectric layer 154.

As shown in FIG. 3E, another etch operation is performed to etch through the dielectric layer 154, through the oxide layer 152, and through the ESL 116b to form recesses 310. The etch operation may include, for example, a gas-based etch operation in which a different type of etchant is used, as compared to the etchant that was used to transfer the pattern to the dielectric masking layer 308. Thus, the semiconductor device 100 may be transferred from a first etch tool (in which the pattern was transferred to the dielectric masking layer 308) to a second etch tool (in which the dielectric layer 154, the oxide layer 152, and the ESL 116b are etched) using a wafer/die transport tool to reduce the likelihood of cross-contamination between the first and second etch tools. Alternatively, an etch tool that has multiple processing chambers (e.g., a cluster tool) may be used, and the semiconductor device 100 may be transferred between processing chambers of the etch tool for etching using different types of etchants.

The gas-based etchant that is used to etch the dielectric layer 154, the oxide layer 152, and the ESL 116b, may include a fluorine-based gas etchant that has a higher etch rate for the dielectric materials of the dielectric layer 154, the oxide layer 152, and the ESL 116b compared to the etch rate of the dielectric masking layer 308. This enables the dielectric layer 154, the oxide layer 152, and the ESL 116b to be etched with minimal etching to the dielectric masking layer 308. The fluorine-based etchant may include a carbon fluoride-based (CFₓ) gas etchant such as a carbon tetrafluoride (CF₄) gas etchant.

In some implementations, a plurality of etch operations (e.g., a plurality of gas-based etch operations using the fluorine-based etchant) are performed to form the recesses 310. For example, a first etch operation (referred to as a “main etch” operation) may be performed to form the recesses 310 to the ESL 116b. In other words, etching in the first etch operation stops at the ESL 116b such that the ESL 116b remains between the bottom of the recesses 310 and the underlying metallization structures 122f, 122g, and 122h. The ESL 116b is kept over the metallization structures 122f, 122g, and 122h to prevent the metallization structures 122f, 122g, and 122h from being exposed to oxygen and other contaminants that might otherwise result in oxidation of the metallization structures 122f, 122g, and 122h.

A second etch operation (referred to as a “linear removal” etch operation) may be performed to etch through the ESL 116b at the bottom of the recesses 310 to extend the recesses 310 through the ESL 116b and to the underlying metallization structures 122f, 122g, and 122h. Thus, the metallization structures 122f, 122g, and 122h are exposed through the recesses 310 after the third etch operation. The second etch operation may be performed using the second etch tool and using a fluorine-based etchant such as a carbon fluoride-based (CFₓ such as CF₄) gas etchant. The dielectric masking layer 308 remains on the dielectric layer 154 during the second etch operation to etch through the ESL 116b such that the dielectric masking layer 308 protects the dielectric layer 154 from being etched, which reduces the likelihood of critical dimension reduction. Following exposure of the metallization structures 122f, 122g, and 122h in the recesses 310, the dielectric masking layer 308 may be removed from the dielectric layer 154.

As shown in FIG. 3F, the liner layer 148 may be deposited on the sidewalls and on the bottom surfaces of the recesses 310. The bottom surfaces of the recesses 310 correspond to the top surfaces of the metallization structures 122f, 122g, and 122h, and thus the liner layer 148 may be in physical contact with the top surfaces of the metallization structures 122f, 122g, and 122h. The liner layer 148 may also be deposited on the top surface of the dielectric layer 154 between adjacent recesses 310, and removed from the top surface of the dielectric layer 154 in a subsequent CMP operation. In some implementations, a deposition tool is used to conformally deposit the liner layer 148 such that the liner layer 148 conforms to the profile of the recesses 310. In some implementations, a conformal CVD technique and/or an ALD technique is used to deposit the liner layer 148.

The fill layer 146 may be deposited on the liner layer 148. The fill layer 146 may be deposited such that the fill layer 146 fills the remaining areas of the recesses 310. The fill layer 146 may also be deposited on the top surface of the liner layer 148 between recesses 310, and removed along with the liner layer 148 from the top surface of the dielectric layer 154 in a subsequent CMP operation. In some implementations, a deposition tool is used to deposit the fill layer 146 using a PVD technique, a CVD technique, an ALD technique, and/or another suitable deposition technique to form the bottom interconnect structures 144 including the fill layers 146 and the liner layers 148.

As shown in FIG. 3G, in some implementations, a blanket bottom electrode layer 312 is deposited on the bottom interconnect structures 144 and on portions of the dielectric layer 154 in which the bottom interconnect structures 144 may be formed. A deposition tool may be used to deposit the blanket bottom electrode layer 312 using a CVD technique, a PVD technique, an ALD technique, an electroplating technique, and/or another suitable deposition technique. The material of the blanket bottom electrode layer 312 may be deposited in one or more deposition operations. In some implementations, a seed layer is first deposited, and the material of the blanket bottom electrode layer 312 is deposited on the seed layer. As shown in FIG. 3H by the reduced thickness (e.g., z-direction dimension) of the blanket bottom electrode layer 312, in some implementations, a planarization tool is used to perform a planarization operation (e.g., a CMP operation) to planarize the blanket bottom electrode layer 312 after the blanket bottom electrode layer 312 is deposited. The blanket bottom electrode layer 312 may include one or more electrically conductive materials to be used for the bottom electrode layers 134. Examples include metals such as molybdenum (Mo), nickel (Ni), iridium (Ir), and chromium (Cr), as well as metal nitrides such as titanium nitride (TiN) or tantalum nitride (TaN), among other examples.

As further shown in FIG. 3H, a deposition tool may form a blanket MTJ structure 314 over and/or on the top surface of the blanket bottom electrode layer 312. In some implementations, a deposition tool forms the blanket MTJ structure 314 using a spin-coating technique, a CVD technique, a PVD technique, an ALD technique, and/or another deposition technique. In some implementations, a planarization tool is used to perform a planarization operation (e.g., a CMP operation) to planarize the blanket MTJ structure 314 after the blanket MTJ structure 314 is deposited. The blanket MTJ structure 314 may include ferromagnetic layers separated by a tunnel barrier layer. The ferromagnetic layers may include ferrous materials including a combination of iron (Fe) and one or more of cobalt (Co), boron (B), and/or nickel (Ni), among other examples, and the tunnel barrier layer may include a crystalline material, such as magnesium oxide (MgO) and/or another suitable material.

As further shown in FIG. 3E, a deposition tool may form a mask structure, including a top electrode mask layer 316 and a dielectric mask layer 318 on the top electrode mask layer 316, over and/or on the top surface of the blanket MTJ structure 314. In some implementations, a deposition tool forms the mask structure, including a top electrode mask layer 316 and a dielectric mask layer 318, using a spin-coating technique, a CVD technique, a PVD technique, an ALD technique, and/or another deposition technique. The top electrode mask layer 316 may include one or more electrically conductive materials to be used for the top electrode layers 138. Examples include metals such as molybdenum (Mo), nickel (Ni), iridium (Ir), and chromium (Cr), as well as metal nitrides such as titanium nitride (TiN) or tantalum nitride (TaN), among other examples. In some implementations, the dielectric mask layer 318 includes tetraethyl orthosilicate (TEOS), an oxide, or another suitable dielectric material. In some implementations, the mask structure may be patterned in an etching operation to form a plurality of mask structure portions spaced apart from each other in the x-direction on the blanket MTJ structure 314. Each mask structure portion includes a portion of the top electrode mask layer 316 and a portion of the dielectric mask layer 318 on the portion of the top electrode mask layer 316.

As shown in FIG. 3I, portions of the blanket MTJ structure 314 and the blanket bottom electrode layer 312 are removed in one or more etching processes, where the plurality of mask structure portions, each including a portion of the top electrode mask layer 316 and a portion of the dielectric mask layer 318 on the portion of the top electrode mask layer 316, are used as masks that cover portions of the blanket MTJ structure 314 and underlying portions of the blanket bottom electrode layer 312. Exposed portions of the blanket MTJ structure 314 and of the blanket bottom electrode layer 312 that are not covered by the plurality of mask structure portions are removed in the one or more etching processes to pattern the blanket MTJ structure 314 into the MTJ structures 136 and to pattern the blanket bottom electrode layer 312 into the bottom electrode layers 134. In addition, the one or more etching processes result in removal of the portions of the dielectric mask layers 318, and patterning of the remaining portions of the top electrode mask layers 316 into the top electrode layers 138, where each top electrode layer 138 may have a curved top surface. In some implementations, an etch tool uses a wet etch technique, a dry etch technique, a plasma-enhanced etch technique, and/or another type of etch technique to perform the one or more etching processes.

The resulting patterned MTJ structures 136 and patterned bottom electrode layers 134 each include angled side surfaces, such that the MTJ structures 136 and bottom electrode layers 134 each taper to a larger width (e.g., x-direction dimension) in the downward z-direction. The one or more etching processes cause removal of portions of the dielectric layer 154 between and/or adjacent to the memory devices 132a-132c to result in a curved profile of the top surfaces of the portions of the dielectric layer 154 between and/or adjacent to the memory devices 132a-132c.

As shown in FIG. 3I, a first spacer layer 140 is conformally deposited on exposed side surfaces of the bottom electrode layers 134, on exposed side surfaces of the MTJ structures 136, on exposed side and top surfaces of the top electrode layers 138, and on the top surfaces of the portions of the dielectric layer 154 between and/or adjacent to the memory devices 132a-132c. The first spacer layer 140 is deposited on the top surfaces of the dielectric layer 154 in the memory region 126 and in the logic region 128. A deposition tool may be used to deposit the first spacer layer 140 using an ALD technique, a CVD technique, and/or another suitable deposition technique.

As shown in FIG. 3J, an etch tool performs an etch process to remove portions of the first spacer layer 140 from the top surfaces and portions of the side surfaces of top electrode layers 138. A portion of the first spacer layer 140 is further removed from the top surface of the dielectric layer 154 on the side of the semiconductor structure 130 (e.g., at an end of the memory region 126 and in the logic region 128). In some implementations, the etch operation includes a dry etch operation (e.g., a plasma-based etch operation, a gas-based etch operation), a wet chemical etch operation, and/or another type of etch operation.

As further shown in FIG. 3J, the second spacer layer 142 is conformally deposited on exposed surfaces of the remaining portions of the first spacer layer 140 (which may be referred to herein as first spacer layers 140), on exposed side and top surfaces of the top electrode layers 138, and on the top surfaces of the portions of the dielectric layer 154 between and/or adjacent to the memory devices 132a-132c where the first spacer layer 140 was removed. The second spacer layer 142 is deposited on the top surfaces of the dielectric layer 154 in the memory region 126 and in the logic region 128. A deposition tool may be used to deposit the second spacer layer 142 using an ALD technique, a CVD technique, and/or another suitable deposition technique.

As shown in FIG. 3K, the PEALD oxide layer 156 is conformally deposited on exposed surfaces of the second spacer layer 142. A deposition tool may be used to deposit the PEALD oxide layer 156 using an ALD technique, a CVD technique, and/or another suitable deposition technique. As shown in FIG. 3L, an etch tool performs an etch process to remove portions of the PEALD oxide layer 156 from the top surfaces and portions of the side surfaces of top electrode layers 138. A portion of the PEALD oxide layer 156 is further removed from part of the top surface of the second spacer layer 142 on the side of the semiconductor structure 130 (e.g., at an end of the memory region 126 and in the logic region 128). In some implementations, the etch operation includes a dry etch operation (e.g., a plasma-based etch operation, a gas-based etch operation), a wet chemical etch operation, and/or another type of etch operation.

As shown in FIG. 3M, an etch tool performs an etch process to remove exposed portions of the second spacer layer 142 from the top surfaces and portions of the side surfaces of top electrode layers 138. A portion of the second spacer layer 142 is further removed from part of the top surface of the dielectric layer 154 on the side of the semiconductor structure 130 (e.g., at an end of the memory region 126 and in the logic region 128) to expose part of the dielectric layer 154. In some implementations, the etch operation includes a dry etch operation (e.g., a plasma-based etch operation, a gas-based etch operation), a wet chemical etch operation, and/or another type of etch operation. Remaining portions of the second spacer layer 142 may be referred to herein as second spacer layers 142. The remaining portions of the first spacer layer 140 (e.g., first spacer layers 140), and the remaining portions of the second spacer layer 142 (e.g., second spacer layers 142) are formed on side surfaces of the bottom electrode layer 134, the MTJ structure 136, and a lower portion of the top electrode layer 138 for each of the memory devices 132a-132c. The first and second spacer layers 140 and 142 are further formed on the top surfaces of the portions of the ILD layer 114c between and/or adjacent to the memory devices 132a-132c.

As shown in FIG. 3N, an etch tool performs an etch process to remove part of an exposed portion of the dielectric layer 154 from part of the top surface of the oxide layer 152 on the side of the semiconductor structure 130 (e.g., at an end of the memory region 126 and in the logic region 128). The removal exposes part of the underlying oxide layer 152. As shown in FIG. 3O, an etch tool performs an etch process to remove an exposed portion of the oxide layer 152 from part of the top surface of the ESL 116b on the side of the semiconductor structure 130 (e.g., at an end of the memory region 126 and in the logic region 128). In some implementations, the etch operations include a dry etch operation (e.g., a plasma-based etch operation, a gas-based etch operation), a wet chemical etch operation, and/or another type of etch operation.

As shown in FIG. 3P, the ILD layer 114c is deposited over the memory devices 132a-132c in the memory region 126, including on the exposed surfaces of the top electrode layers 138, and on the PEALD oxide layer 156. The ILD layer 114c is further deposited on the ESL 116b on the side of the semiconductor structure 130 (e.g., at an end of the memory region 126 and in the logic region 128). A deposition tool may be used to deposit the ILD layer 114c using a PVD technique, an ALD technique, a CVD technique, an oxidation technique, and/or another suitable deposition technique.

Following deposition of the ILD layer 114c, a dielectric masking layer 320 is conformally deposited on top surfaces of the ILD layer 114c. A deposition tool may be used to deposit the dielectric masking layer 320 using a PVD technique, an ALD technique, a CVD technique, an oxidation technique, and/or another suitable deposition technique.

A photoresist layer may be formed above the dielectric masking layer 320, and a pattern may be formed in the photoresist layer. An etch tool may be used to etch the dielectric masking layer 320 based on the pattern in the photoresist layer, to transfer the pattern to the dielectric masking layer 320, and remove part of the dielectric masking layer 320 to expose an underlying portion of the ILD layer 114c. As shown in FIG. 3Q, an etch operation may be performed to etch the ILD layer 114c to remove part of the exposed portion of the ILD layer 114c. The etch operation may include, for example, a gas-based etch operation in which a different type of etchant is used, as compared to the etchant that was used to transfer the pattern to the dielectric masking layer 320.

As shown in FIG. 3R, a planarization tool is used to perform a planarization operation (e.g., a CMP operation) to planarize the ILD layer 114c to remove excess portions of the ILD layer 114c and to remove the remaining portions of the dielectric masking layer 320.

As shown in FIG. 3S, following the planarization operation on the ILD layer 114c, a dielectric masking layer 322 is deposited on top surfaces of the ILD layer 114c. A deposition tool may be used to deposit the dielectric masking layer 322 using a PVD technique, an ALD technique, a CVD technique, an oxidation technique, and/or another suitable deposition technique.

A photoresist layer 324 may be formed above the dielectric masking layer 322, and a pattern may be formed in the photoresist layer. A deposition tool may be used to form the photoresist layer on the dielectric masking layer 322 (e.g., using a spin-coating technique or another suitable deposition technique). In some implementations, a BARC is first deposited on the dielectric masking layer 322, and then the photoresist layer is deposited onto the BARC. An exposure tool may be used to expose the photoresist layer to a radiation source to pattern the photoresist layer. A developer tool may be used to develop and remove portions of the photoresist layer to expose the pattern.

An etch tool may be used to etch the dielectric masking layer 322 based on the pattern in the photoresist layer, to transfer the pattern to the dielectric masking layer 322. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). The etchant may have a higher etch rate for the dielectric masking layer 322 compared to the material of the underlying ILD layer 114c. Thus, the etch operation may stop on the ILD layer 114c, with minimal etching to the ILD layer 114c.

As shown in FIG. 3T, one or more additional etch operations may be performed to etch through the ILD layer 114c and the ESL 116b to form recesses 326 and 328 in the logic region 128, where bottom surfaces of the recesses 326 expose portions of top surfaces of the underlying metallization structures 122i and 122j. The etch operations may include, for example, a gas-based etch operation in which a different type of etchant is used, as compared to the etchant that was used to transfer the pattern to the dielectric masking layer 322. Thus, the semiconductor device 100 may be transferred from a first etch tool (in which the pattern was transferred to the dielectric masking layer 322) to a second etch tool (in which the ILD layer 114c and the ESL 116b are etched) using a wafer/die transport tool to reduce the likelihood of cross-contamination between the first and second etch tools. Alternatively, an etch tool that has multiple processing chambers (e.g., a cluster tool) may be used, and the semiconductor device 100 may be transferred between processing chambers of the etch tool for etching using different types of etchants.

In some implementations, a dual damascene process is used to form the recesses 326 and 328. For example, the recesses 326 may be formed in and/or through a bottom portion of the ILD layer 114c and ESL 116b. The recesses 328 may be formed in the top portion of the ILD layer 114c above the recesses 326.

An interconnect structure-first dual damascene procedure can be performed in which the recesses 326 and 328 are formed by forming the recesses 326 before forming the recesses 328. In some implementations, a trench-first dual damascene procedure can be performed in which the recesses 326 and 328 are formed by forming the recesses 328 before forming the recesses 326.

As shown in FIG. 3U, one or more deposition tools may be used to deposit conductive material 330 in the recesses 328 and 326 to form the metallization structures 122k and 122l, and the interconnect structures 124f and 124g, using a PVD technique, an ALD technique, a CVD technique, an electroplating technique (e.g., an electro-chemical plating technique), and/or another suitable deposition technique. As noted herein, the conductive material to form the metallization structures 122k and 122l and the interconnect structures 124f and 124g may include, for example, tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers are included in the metallization structures 122k and 122l and the interconnect structures 124f and 124g. The one or more liner layers may include barrier liners, adhesion liners, and/or another type of liners. Examples of materials for the one or more liners include tantalum nitride (TaN) and/or titanium nitride (TiN), among other examples.

As shown in FIG. 3V, a planarization tool may be used to planarize the surface of the ILD layer 114c to remove the dielectric masking layer 322, the photoresist layer 324, and excess portions of the conductive material 330 formed on the photoresist layer 324 and the dielectric masking layer 322 and/or over the top surfaces of the ILD layer 114c. Another ESL 116c is deposited over the ILD layer 114c. A deposition tool may be used to deposit the ESL 116c using a PVD technique, an ALD technique, a CVD technique, an oxidation technique, and/or another suitable deposition technique.

As shown in FIG. 3W, the dielectric layer 158 and the ILD layer 114d are deposited on the ESL 116c. A deposition tool may be used to deposit the dielectric layer 158 and the ILD layer 114d using a PVD technique, an ALD technique, a CVD technique, an oxidation technique, and/or another suitable deposition technique. A dielectric masking layer 332 is deposited on top surfaces of the ILD layer 114d. A deposition tool may be used to deposit the dielectric masking layer 332 using a PVD technique, an ALD technique, a CVD technique, an oxidation technique, and/or another suitable deposition technique.

A photoresist layer 334 may be formed above the dielectric masking layer 332, and a pattern may be formed in the photoresist layer. A deposition tool may be used to form the photoresist layer on the dielectric masking layer 332 (e.g., using a spin-coating technique or another suitable deposition technique). In some implementations, a BARC is first deposited on the dielectric masking layer 332, and then the photoresist layer is deposited onto the BARC. An exposure tool may be used to expose the photoresist layer to a radiation source to pattern the photoresist layer. A developer tool may be used to develop and remove portions of the photoresist layer to expose the pattern.

An etch tool may be used to etch the dielectric masking layer 332 based on the pattern in the photoresist layer, to transfer the pattern to the dielectric masking layer 332. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). The etchant may have a higher etch rate for the dielectric masking layer 332 compared to the material of the underlying ILD layer 114d. Thus, the etch operation may stop on the ILD layer 114d, with minimal etching to the ILD layer 114d.

As shown in FIG. 3X, one or more additional etch operations may be performed to etch through the ILD layer 114d, the dielectric layer 158, and the ESL 116c to form recesses 336 and 338 in the memory region 126, and recesses 340 and 342 in the logic region 128, where bottom surfaces of the recesses 336 expose portions of top surfaces of the underlying top electrode layers 138 of the memory devices 132a-132c, and where bottom surfaces of the recesses 340 expose portions of top surfaces of the underlying metallization structures 122k and 122l. In some implementations, the recesses 336 and 340 are simultaneously formed during the same etch operation, and the recesses 338 and 342 are simultaneously formed during the same etch operation. The same mask structure (e.g., dielectric masking layer 332 and photoresist layer 334) is used to form the recesses 336, 338, 340 and 342.

The etch operations may include, for example, a gas-based etch operation in which a different type of etchant is used, as compared to the etchant that was used to transfer the pattern to the dielectric masking layer 332. Thus, the semiconductor device 100 may be transferred from a first etch tool (in which the pattern was transferred to the dielectric masking layer 332) to a second etch tool (in which the ILD layer 114d, the dielectric layer 158, and the ESL 116c are etched) using a wafer/die transport tool to reduce the likelihood of cross-contamination between the first and second etch tools. Alternatively, an etch tool that has multiple processing chambers (e.g., a cluster tool) may be used, and the semiconductor device 100 may be transferred between processing chambers of the etch tool for etching using different types of etchants.

In some implementations, a dual damascene process is used to form the recesses the recesses 336, 338, 340 and 342. For example, the recesses 336 and 340 may be formed in and/or through a bottom portion of the ILD layer 114d, the dielectric layer 158, and ESL 116c. The recesses 338 and 342 may be formed in the top portion of the ILD layer 114d above the recesses 336 and 340, respectively.

An interconnect structure-first dual damascene procedure can be performed in which the recesses 336, 338, 340 and 342 are formed by forming the recesses 336 and 340 before forming the recesses 338 and 342. In some implementations, a trench-first dual damascene procedure can be performed in which the recesses 336, 338, 340 and 342 are formed by forming the recesses 338 and 342 before forming the recesses 336 and 340.

In some implementations, a horizontal (e.g., lateral) dimension D1′ (e.g., x-direction dimension) of each recess 336 may be smaller than a horizontal (e.g., lateral) dimension D2′ (e.g., x-direction dimension) of each recess 340. The smaller horizontal dimension D1′ may be due to a smaller lateral footprint of each of the memory devices 132a-132c and a smaller pitch between the memory devices 132a-132c than other memory devices. For example, the memory devices 132a-132c may be designed in accordance with a 5 nm node and beyond, where a pitch between the memory devices 132a-132c is less than approximately 42 nanometers. The horizontal dimension D1′ of the recesses 336 may be equal to or approximately equal to the horizontal dimension D1 of the interconnect structures 124h-124j that are formed in the recesses 336. The horizontal dimension D2′ of the recesses 340 may be equal to or approximately equal to the horizontal dimension D2 of the interconnect structures 124k and 124l that are formed in the recesses 340.

In some implementations, a vertical dimension D3′ (e.g., z-direction dimension) (e.g., height or depth) of each recess 336 may be greater than a vertical dimension D4′ (e.g., z-direction dimension) of each recess 340. The greater vertical dimension D3′ may be due to a top surface of the top electrode layer 138 of each of the memory devices 132a-132c failing to reach a top surface of the ILD layer 114c and/or a bottom surface of the ESL 116c. As a result, the recesses 336 may be formed through a top portion of the ILD layer 114c to expose the top electrode layer 138 of each of the memory devices 132a-132c. In some implementations, the vertical dimension D3′ of the recesses 336 may be approximately 100 angstroms to approximately 300 angstroms greater than the vertical dimension D4′ of the recesses 340. Alternatively, the vertical dimension D3′ of each of the recesses 336 may be equal to the vertical dimension D4′ of the recesses 340. In the case where the vertical dimensions D3′ and D4′ are equal, the top surfaces of the top electrode layer 138 of each of the memory devices 132a-132c may be co-planar with or approximately co-planar with top surfaces of the metallization structures 122k and 122l. The vertical dimension D3′ of the recesses 336 may be equal to or approximately equal to the vertical dimension D3 of the interconnect structures 124h-124j that are formed in the recesses 336. The vertical dimension D4′ of the recesses 340 may be equal to or approximately equal to the vertical dimension D4 of the interconnect structures 124k and 124l that are formed in the recesses 340.

As shown in FIG. 3Y, one or more deposition tools may be used to deposit conductive material 344 in the recesses 336, 338, 340 and 342 to form the metallization structure 122m and the interconnect structures 124h-124j in the memory region 126, and to form the metallization structure 122n and the interconnect structures 124k and 124l in the logic region 128. The conductive material may be deposited using a PVD technique, an ALD technique, a CVD technique, an electroplating technique (e.g., an electro-chemical plating technique), and/or another suitable deposition technique. As noted herein, the conductive material 344 to form the metallization structures 122m and 122n and the interconnect structures 124h-124l may include, for example, tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers are included in the metallization structures 122m and 122n and the interconnect structures 124h-124l. The one or more liner layers may include barrier liners, adhesion liners, and/or another type of liners. Examples of materials for the one or more liners include tantalum nitride (TaN) and/or titanium nitride (TiN), among other examples.

As shown in FIG. 3Z, a planarization tool may be used to planarize the surface of the ILD layer 114d to remove the dielectric masking layer 332, the photoresist layer 334, and excess portions of the conductive material 344 formed on the photoresist layer 334 and the dielectric masking layer 332 and/or over the top surfaces of the ILD layer 114d. Another ESL 116d is deposited over the ILD layer 114d. A deposition tool may be used to deposit the ESL 116d using a PVD technique, an ALD technique, a CVD technique, an oxidation technique, and/or another suitable deposition technique.

The metallization structure 122m is commonly connected to the top electrode layer 138 of each memory device 132a, 132b, and 132c through the interconnect structures 124h, 124i, and 124j, respectively. The interconnect structures 124h, 124i, and 124j are in direct contact with a surface of the top electrode layer 138 of memory devices 132a, 132b, and 132c, respectively. The interconnect structures 124h, 124i, and 124j are each connected to the metallization structure 122m. In some implementations, the surface of the top electrode layer 138 of each memory device 132a, 132b, and 132c with which the interconnect structures 124h, 124i, and 124j are in direct contact is curved. A top surface of the metallization structure 122m may be co-planar with or approximately co-planar with a top surface of the metallization structure 122n.

The metallization structure 122n is connected to the metallization structure 122k through the interconnect structure 124k, and the metallization structure 122n is connected to the metallization structure 122l through the interconnect structure 124l. The interconnect structures 124k and 124l are in direct contact with a surface of the metallization structure 122k and a surface of the metallization structure 122l, respectively. The interconnect structures 124k and 124l are each connected to the metallization structure 122n.

As indicated above, FIGS. 3A-3Z are provided as an example. Other examples may differ from what is described with regard to FIGS. 3A-3Z.

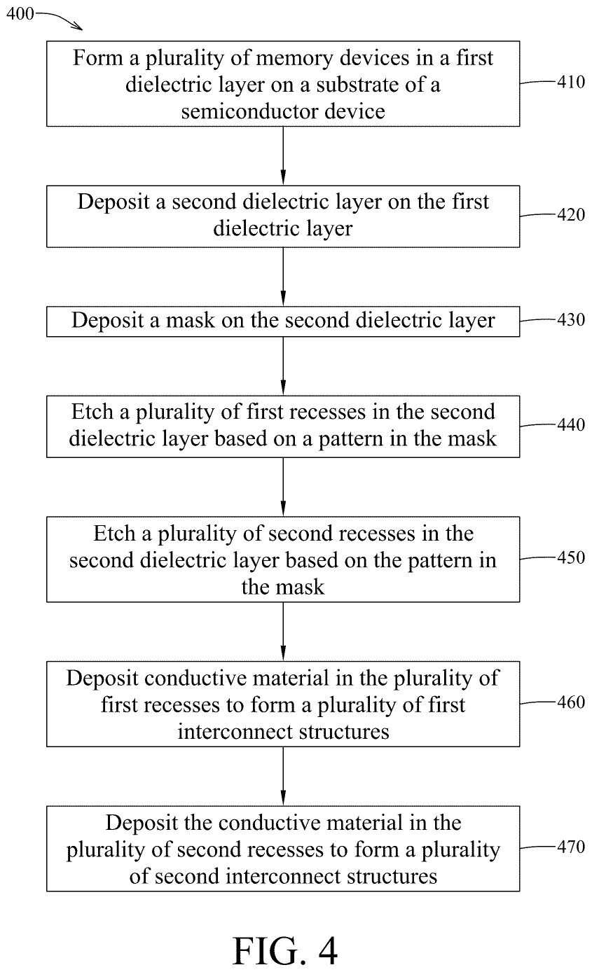

FIG. 4 is a flowchart of an example process 400 associated with a method of forming a semiconductor device. In some implementations, one or more process blocks of FIG. 4 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 4, process 400 may include forming a plurality of memory devices in a first dielectric layer on a substrate of a semiconductor device (block 410). For example, one or more semiconductor processing tools may be used to form a plurality of memory devices (e.g., memory devices 132a-132c) in a first dielectric layer (e.g., ILD layer 114c) on a substrate (e.g., substrate 106) of a semiconductor device (e.g., semiconductor device 100), as described herein. In some implementations, the plurality of memory devices is formed in a first region (e.g., memory region 126) of the semiconductor device. In some implementations, each memory device of the plurality of memory devices includes a magnetic tunnel junction (MTJ) structure (e.g., MTJ structure 136), and an electrode layer (e.g., top electrode layer 138) on the MTJ structure.

As further shown in FIG. 4, process 400 may include depositing a second dielectric layer on the first dielectric layer (block 420). For example, one or more semiconductor processing tools may be used to deposit a second dielectric layer (e.g., ILD layer 114d) on the first dielectric layer, as described herein. In some implementations, the first dielectric layer and the second dielectric layer are arranged in a first direction (e.g., z-direction).

As further shown in FIG. 4, process 400 may include depositing a mask on the second dielectric layer (block 430). For example, one or more semiconductor processing tools may be used to deposit a mask (e.g., dielectric masking layer 332, photoresist layer 334) on the second dielectric layer, as described herein.

As further shown in FIG. 4, process 400 may include etching a plurality of first recesses in the second dielectric layer based on a pattern in the mask (block 440). For example, one or more semiconductor processing tools may be used to etch a plurality of first recesses (e.g., recesses 336) in the second dielectric layer based on a pattern in the mask, as described herein. In some implementations, the plurality of first recesses respectively expose respective ones of the plurality of memory devices.

As further shown in FIG. 4, process 400 may include etching a plurality of second recesses in the second dielectric layer based on the pattern in the mask (block 450). For example, one or more semiconductor processing tools may be used to etch a plurality of second recesses (e.g., recesses 340) in the second dielectric layer based on the pattern in the mask, as described herein. In some implementations, the plurality of second recesses is in a second region (e.g., logic region 128) of the semiconductor device disposed on a side of the first region in a second direction (e.g., x-direction) perpendicular to the first direction. In some implementations, the plurality of second recesses respectively expose respective ones (e.g., metallization structure 122k, 122l) of a plurality of metallization structures in the first dielectric layer.

As further shown in FIG. 4, process 400 may include depositing conductive material in the plurality of first recesses to form a plurality of first interconnect structures (block 460). For example, one or more semiconductor processing tools may be used to deposit conductive material (e.g., conductive material 344) in the plurality of first recesses to form a plurality of first interconnect structures (e.g., interconnect structures 124h, 124i, 124j), as described herein. In some implementations, the plurality of first interconnect structures respectively contact the respective ones of the plurality of memory devices.

As further shown in FIG. 4, process 400 may include depositing the conductive material in the plurality of second recesses to form a plurality of second interconnect structures (block 470). For example, one or more semiconductor processing tools may be used to deposit the conductive material in the plurality of second recesses to form a plurality of second interconnect structures (e.g., interconnect structures 124k, 124l), as described herein. In some implementations, the plurality of second interconnect structures respectively contact the respective ones of the plurality of metallization structures.

Process 400 may include additional implementations, such as any single implementation or any combination of implementations described below and/or in connection with one or more other processes described elsewhere herein.

In a first implementation, process 400 includes etching a third recess (e.g., recess 338) in the second dielectric layer based on the pattern in the mask, where the third recess is formed over the plurality of first recesses, and etching a fourth recess (e.g., recess 342) in the second dielectric layer based on the pattern in the mask, where the fourth recess is formed over the plurality of second recesses.

In a second implementation, alone or in combination with the first implementation, process 400 includes depositing the conductive material in the third recess to form a first metallization structure (e.g., metallization structure 122m), where the first metallization structure contacts surfaces of each first interconnect structure of the plurality of first interconnect structures, and depositing the conductive material in the fourth recess to form a second metallization structure (e.g., metallization structure 122n), where the second metallization structure contacts surfaces of each second interconnect structure of the plurality of second interconnect structures.

In a third implementation, alone or in combination with one or more of the first and second implementations, a dimension (e.g., horizontal dimension D1) in the second direction of each first recess and each first interconnect structure is smaller than a dimension (e.g., horizontal dimension D2) in the second direction of each second recess and each second interconnect structure.

In a fourth implementation, alone or in combination with one or more of the first through third implementations, a dimension (e.g., vertical dimension D3) in the first direction of each first recess and each first interconnect structure is approximately equal to a dimension (e.g., vertical dimension D4) in the first direction of each second recess and each second interconnect structure.

In a fifth implementation, alone or in combination with one or more of the first through fourth implementations, a vertical dimension (e.g., vertical dimension D3) in the first direction of each first recess and each first interconnect structure is larger than a dimension (e.g., vertical dimension D4) in the first direction of each second recess and each second interconnect structure.

In a sixth implementation, alone or in combination with one or more of the first through fifth implementations, forming the plurality of memory devices includes depositing a mask structure (e.g., top electrode mask layer 316, dielectric mask layer 318) on a blanket MTJ structure (e.g., blanket MTJ structure 314), where the mask structure includes a dielectric layer (e.g., dielectric mask layer 318) on a metal layer (e.g., top electrode mask layer 316), etching the mask structure to form a patterned mask structure, and etching the blanket MTJ structure based on the patterned mask structure to form the MTJ structure of each memory device, where the metal layer of the mask structure is patterned into the electrode layer of each memory device.

In a seventh implementation, alone or in combination with one or more of the first through sixth implementations, process 400 includes forming the plurality of metallization structures in the first dielectric layer after forming the plurality of memory devices, where the plurality of metallization structures is formed in the second region on a side of the plurality of memory devices in the second direction.

In an eighth implementation, alone or in combination with one or more of the first through seventh implementations, forming the plurality of metallization structures includes depositing an additional mask (e.g., dielectric masking layer 322, photoresist layer 324) on the first dielectric layer over the plurality of memory devices, etching a plurality of third recesses (e.g., recesses 328) in the first dielectric layer based on a pattern in the additional mask, and depositing additional conductive material (e.g., conductive material 330) in the plurality of third recesses to form the plurality of metallization structures.

Although FIG. 4 shows example blocks of process 400, in some implementations, process 400 includes additional blocks, fewer blocks, different blocks, or differently arranged blocks than those depicted in FIG. 4. Additionally, or alternatively, two or more of the blocks of process 400 may be performed in parallel.

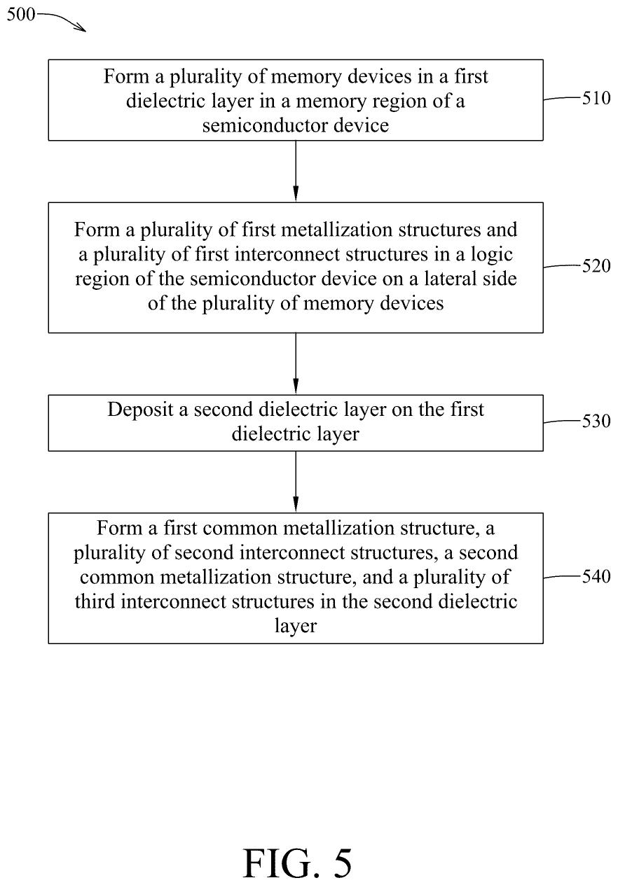

FIG. 5 is a flowchart of an example process 500 associated with a method of forming a semiconductor device. In some implementations, one or more process blocks of FIG. 5 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 5, process 500 may include forming a plurality of memory devices in a first dielectric layer in a memory region of a semiconductor device (block 510). For example, one or more semiconductor processing tools may be used to form a plurality of memory devices (e.g., memory devices 132a-132c) in a first dielectric layer (e.g., ILD layer 114c) in a memory region (e.g., memory region 126) of a semiconductor device (e.g., semiconductor device 100), as described herein.

As further shown in FIG. 5, process 500 may include forming a plurality of first metallization structures and a plurality of first interconnect structures in a logic region of the semiconductor device on a lateral side of the plurality of memory devices based on a pattern in the first mask structure (block 520). For example, one or more semiconductor processing tools may be used to form a plurality of first metallization structures (e.g., metallization structures 122k, 122i) and a plurality of first interconnect structures (e.g., interconnect structures 124f, 124g) in a logic region (e.g., logic region 128) of the semiconductor device on a lateral side of the plurality of memory devices, as described herein.

As further shown in FIG. 5, process 500 may include depositing a second dielectric layer on the first dielectric layer (block 530). For example, one or more semiconductor processing tools may be used to deposit a second dielectric layer (e.g., ILD layer 114d) on the first dielectric layer, as described herein.

As further shown in FIG. 5, process 500 may include forming a first common metallization structure, a plurality of second interconnect structures, a second common metallization structure, and a plurality of third interconnect structures in the second dielectric layer (block 540). For example, one or more semiconductor processing tools may be used to form a first common metallization structure (e.g., metallization structure 122m), a plurality of second interconnect structures (e.g., interconnect structures 124h-124j), a second common metallization structure (e.g., metallization structure 122n), and a plurality of third interconnect structures (e.g., interconnect structures 124k, 124l) in the second dielectric layer, as described herein. In some implementations, the first common metallization structure and the plurality of second interconnect structures are located in the memory region over the plurality of memory devices. In some implementations, the second common metallization structure and the plurality of third interconnect structures are located in the logic region on a lateral side of the first common metallization structure and the plurality of second interconnect structures.

Process 500 may include additional implementations, such as any single implementation or any combination of implementations described below and/or in connection with one or more other processes described elsewhere herein.

In a first implementation, forming the first common metallization structure and the plurality of second interconnect structures includes etching a recess (e.g., recess 338) for the first common metallization structure in the second dielectric layer, etching a plurality of recesses (e.g., recesses 336) for the plurality of second interconnect structures, where each of the plurality of recesses for the plurality of second interconnect structures exposes a surface of an electrode of an underlying memory device of the plurality of memory devices, and depositing conductive material in the recess for the first common metallization structure, and in the plurality of recesses for the plurality of second interconnect structures.

In a second implementation, alone or in combination with the first implementation, forming the second common metallization structure and the plurality of third interconnect structures includes etching a recess (e.g., recess 342) for the second common metallization structure in the second dielectric layer, etching a plurality of recesses (e.g., recesses 340) for the plurality of third interconnect structures, where each of the plurality of recesses for the plurality of third interconnect structures exposes a surface of an underlying first metallization structure of the plurality of first metallization structures, and depositing the conductive material in the recess for the second common metallization structure, and in the plurality of recesses for the plurality of third interconnect structures.

In a third implementation, alone or in combination with one or more of the first and second implementations, the first common metallization structure is connected to each of the plurality of second interconnect structures, where the second common metallization structure is connected to each of the plurality of third interconnect structures.

In a fourth implementation, alone or in combination with one or more of the first through third implementations, a top surface of the first common metallization structure is approximately co-planar with a top surface of the second common metallization structure.

Although FIG. 5 shows example blocks of process 500, in some implementations, process 500 includes additional blocks, fewer blocks, different blocks, or differently arranged blocks than those depicted in FIG. 5. Additionally, or alternatively, two or more of the blocks of process 500 may be performed in parallel.

In this way, respective vias of a plurality of vias are commonly connected to an overlying metallization layer, and land on respective top electrode layers of different memory devices. The vias and metallization layer that are connected to the memory devices in a memory region of a semiconductor device may have the same structure as or a similar structure to vias and a metallization layer in an adjacent logic region. As a result, the vias and metallization layers in the memory and logic regions may be manufactured using the same etching and deposition processes. Accordingly, processing to manufacture the vias and a metallization structure in the memory region and corresponding vias and a metallization structure in a logic region requires fewer masks and fewer steps than processing to manufacture other arrangements of metallization structures and vias. The simplified device manufacturing may result in fewer design errors, resulting in increased device performance and reliability.

As described in greater detail above, some implementations described herein provide a method. The method includes forming a plurality of memory devices in a first dielectric layer on a substrate of a semiconductor device, where the plurality of memory devices is formed in a first region of the semiconductor device, and where each memory device of the plurality of memory devices includes a magnetic tunnel junction (MTJ) structure, and an electrode layer on the MTJ structure. The method includes depositing a second dielectric layer on the first dielectric layer, where the first dielectric layer and the second dielectric layer are arranged in a first direction. The method includes depositing a mask on the second dielectric layer. The method includes etching a plurality of first recesses in the second dielectric layer based on a pattern in the mask, where the plurality of first recesses respectively expose respective ones of the plurality of memory devices. The method includes etching a plurality of second recesses in the second dielectric layer based on the pattern in the mask, where the plurality of second recesses is in a second region of the semiconductor device disposed on a side of the first region in a second direction perpendicular to the first direction, and where the plurality of second recesses respectively expose respective ones of a plurality of metallization structures in the first dielectric layer. The method includes depositing conductive material in the plurality of first recesses to form a plurality of first interconnect structures, where the plurality of first interconnect structures respectively contact the respective ones of the plurality of memory devices. The method includes depositing the conductive material in the plurality of second recesses to form a plurality of second interconnect structures, where the plurality of second interconnect structures respectively contact the respective ones of the plurality of metallization structures.

As described in greater detail above, some implementations described herein provide a method. The method includes forming a plurality of memory devices in a first dielectric layer in a memory region of a semiconductor device. The method includes forming a plurality of first metallization structures and a plurality of first interconnect structures in a logic region of the semiconductor device on a lateral side of the plurality of memory devices. The method includes depositing a second dielectric layer on the first dielectric layer. The method includes forming a first common metallization structure, a plurality of second interconnect structures, a second common metallization structure, and a plurality of third interconnect structures in the second dielectric layer, where the first common metallization structure and the plurality of second interconnect structures are located in the memory region over the plurality of memory devices, and where the second common metallization structure and the plurality of third interconnect structures are located in the logic region on a lateral side of the first common metallization structure and the plurality of second interconnect structures.

As described in greater detail above, some implementations described herein provide a semiconductor device. The semiconductor device includes a device layer. The semiconductor device includes an interconnect layer disposed over the device layer, where the interconnect layer includes a plurality of dielectric layers, where the plurality of dielectric layers include a plurality of metal lines disposed in the plurality of dielectric layers, where a first metal line in a first dielectric layer of the plurality of dielectric layers is spaced apart from a second metal line in a second dielectric layer of the plurality of dielectric layers, and where the first metal line is electrically coupled to the second metal line by a first via in the second dielectric layer. The semiconductor device includes a plurality of memory devices arranged side-by-side in the interconnect layer, where each memory device of the plurality of memory devices includes a first electrode layer, a magnetic tunnel junction (MTJ) structure on the first electrode layer, and a second electrode layer on the MTJ structure. The interconnect layer further includes a plurality of second vias disposed in the second dielectric layer, where each second via of the plurality of second vias is disposed between a third metal line in the second dielectric layer and the second electrode layer of each memory device of the plurality of memory devices, and where the third metal line is in a same metallization level as the second metal line.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a plurality of memory devices in a first dielectric layer on a substrate of a semiconductor device,
wherein the plurality of memory devices is formed in a first region of the semiconductor device, and
wherein each memory device of the plurality of memory devices comprises:
a magnetic tunnel junction (MTJ) structure; and
an electrode layer on the MTJ structure;
depositing a second dielectric layer on the first dielectric layer,
wherein the first dielectric layer and the second dielectric layer are arranged in a first direction;
depositing a mask on the second dielectric layer;
etching a plurality of first recesses in the second dielectric layer based on a pattern in the mask,
wherein the plurality of first recesses respectively expose respective ones of the plurality of memory devices;
etching a plurality of second recesses in the second dielectric layer based on the pattern in the mask,
wherein the plurality of second recesses is in a second region of the semiconductor device disposed on a side of the first region in a second direction perpendicular to the first direction, and
wherein the plurality of second recesses respectively expose respective ones of a plurality of metallization structures in the first dielectric layer;
depositing conductive material in the plurality of first recesses to form a plurality of first interconnect structures,
wherein the plurality of first interconnect structures respectively contact the respective ones of the plurality of memory devices; and
depositing the conductive material in the plurality of second recesses to form a plurality of second interconnect structures,
wherein the plurality of second interconnect structures respectively contact the respective ones of the plurality of metallization structures.

2. The method of claim 1, further comprising:
etching a third recess in the second dielectric layer based on the pattern in the mask,
wherein the third recess is formed over the plurality of first recesses; and
etching a fourth recess in the second dielectric layer based on the pattern in the mask,
wherein the fourth recess is formed over the plurality of second recesses.

3. The method of claim 2, further comprising:
depositing the conductive material in the third recess to form a first metallization structure,
wherein the first metallization structure contacts surfaces of each first interconnect structure of the plurality of first interconnect structures; and
depositing the conductive material in the fourth recess to form a second metallization structure,
wherein the second metallization structure contacts surfaces of each second interconnect structure of the plurality of second interconnect structures.

4. The method of claim 1, wherein a dimension in the second direction of each first recess and each first interconnect structure is smaller than a dimension in the second direction of each second recess and each second interconnect structure.

5. The method of claim 1, wherein a dimension in the first direction of each first recess and each first interconnect structure is approximately equal to a dimension in the first direction of each second recess and each second interconnect structure.

6. The method of claim 1, wherein a vertical dimension in the first direction of each first recess and each first interconnect structure is larger than a dimension in the first direction of each second recess and each second interconnect structure.

7. The method of claim 1, wherein forming the plurality of memory devices comprises:
depositing a mask structure on a blanket MTJ structure,
wherein the mask structure comprises a dielectric layer on a metal layer;
etching the mask structure to form a patterned mask structure; and
etching the blanket MTJ structure based on the patterned mask structure to form the MTJ structure of each memory device,
wherein the metal layer of the mask structure is patterned into the electrode layer of each memory device.

8. The method of claim 1, further comprising forming the plurality of metallization structures in the first dielectric layer after forming the plurality of memory devices,
wherein the plurality of metallization structures is formed in the second region on a side of the plurality of memory devices in the second direction.

9. The method of claim 8, wherein forming the plurality of metallization structures comprises:
depositing an additional mask on the first dielectric layer over the plurality of memory devices;
etching a plurality of third recesses in the first dielectric layer based on a pattern in the additional mask; and
depositing additional conductive material in the plurality of third recesses to form the plurality of metallization structures.

10. A method, comprising:
forming a plurality of memory devices in a first dielectric layer in a memory region of a semiconductor device;
forming a plurality of first metallization structures and a plurality of first interconnect structures in a logic region of the semiconductor device on a lateral side of the plurality of memory devices;
depositing a second dielectric layer on the first dielectric layer; and
forming a first common metallization structure, a plurality of second interconnect structures, a second common metallization structure, and a plurality of third interconnect structures in the second dielectric layer,
wherein the first common metallization structure and the plurality of second interconnect structures are located in the memory region over the plurality of memory devices, and
wherein the second common metallization structure and the plurality of third interconnect structures are located in the logic region on a lateral side of the first common metallization structure and the plurality of second interconnect structures.

11. The method of claim 10, wherein forming the first common metallization structure and the plurality of second interconnect structures comprises:
etching a recess for the first common metallization structure in the second dielectric layer;
etching a plurality of recesses for the plurality of second interconnect structures,
wherein each of the plurality of recesses for the plurality of second interconnect structures exposes a surface of an electrode of an underlying memory device of the plurality of memory devices; and
depositing conductive material in the recess for the first common metallization structure, and in the plurality of recesses for the plurality of second interconnect structures.

12. The method of claim 11, wherein forming the second common metallization structure and the plurality of third interconnect structures comprises:
etching a recess for the second common metallization structure in the second dielectric layer;
etching a plurality of recesses for the plurality of third interconnect structures,
wherein each of the plurality of recesses for the plurality of third interconnect structures exposes a surface of an underlying first metallization structure of the plurality of first metallization structures; and
depositing the conductive material in the recess for the second common metallization structure, and in the plurality of recesses for the plurality of third interconnect structures.

13. The method of claim 10, wherein the first common metallization structure is connected to each of the plurality of second interconnect structures, and
wherein the second common metallization structure is connected to each of the plurality of third interconnect structures.

14. The method of claim 10, wherein a top surface of the first common metallization structure is approximately co-planar with a top surface of the second common metallization structure.

15. A semiconductor device, comprising:
a device layer;
an interconnect layer disposed over the device layer,
wherein the interconnect layer comprises a plurality of dielectric layers,
wherein the plurality of dielectric layers comprise a plurality of metal lines disposed in the plurality of dielectric layers,
wherein a first metal line in a first dielectric layer of the plurality of dielectric layers is spaced apart from a second metal line in a second dielectric layer of the plurality of dielectric layers, and
wherein the first metal line is electrically coupled to the second metal line by a first via in the second dielectric layer;
a plurality of memory devices arranged side-by-side in the interconnect layer,
wherein each memory device of the plurality of memory devices comprises:
a first electrode layer;
a magnetic tunnel junction (MTJ) structure on the first electrode layer; and
a second electrode layer on the MTJ structure,
wherein the interconnect layer further comprises a plurality of second vias disposed in the second dielectric layer,
wherein each second via of the plurality of second vias is disposed between a third metal line in the second dielectric layer and the second electrode layer of each memory device of the plurality of memory devices, and
wherein the third metal line is in a same metallization level as the second metal line.

16. The semiconductor device of claim 15, wherein each second via of the plurality of second vias lands on a top surface of the second electrode layer of each memory device of the plurality of memory devices.

17. The semiconductor device of claim 16, wherein the top surface of the second electrode layer of each memory device is approximately co-planar with a top surface of the first metal line.

18. The semiconductor device of claim 15, wherein a lateral dimension of each second via of the plurality of second vias is smaller than a lateral dimension of the first via.

19. The semiconductor device of claim 15, wherein a vertical dimension of each second via of the plurality of second vias is approximately equal to a vertical dimension of the first via.

20. The semiconductor device of claim 15, wherein a vertical dimension of each second via of the plurality of second vias is larger than a vertical dimension of the first via.
